(19) United States
(12) Patent Application Publication
(10) Pub. No.: US 2024/0297197 A1
(43) Pub. Date: Sep. 5, 2024

(54) SEMICONDUCTOR DEVICE, SOLID-STATE IMAGING DEVICE, AND METHOD FOR MANUFACTURING SEMICONDUCTOR DEVICE

(71) Applicant: SONY SEMICONDUCTOR SOLUTIONS CORPORATION, KANAGAWA (JP)

(72) Inventor: TAKAHIRO KAMEI, KANAGAWA (JP)

(21) Appl. No.: 18/700,127

(22) PCT Filed: Aug. 25, 2022
(86) PCT No.: PCT/JP2022/032008

§ 371 Date: Apr. 10, 2024

(30) Foreign Application Priority Data
Oct. 18, 2021 (JP) 2021-170226

(51) Int. Cl. H01L 27/146

(52) U.S. Cl. CPC H01L 27/14636; H01L 27/14603; H01L 27/14632; H01L 27/14687

(57) ABSTRACT

Provided is a semiconductor device that can improve embeddability around an element part provided on a substrate.

The semiconductor device according to the present technique includes the substrate and the at least one element part provided on the substrate. At least a part of the element part is shaped to increase in width toward the substrate, the part including a side opposite to a side near the substrate. According to the semiconductor device of the present technique, the semiconductor device can be provided with enhanced embeddability around the element part provided on the substrate.

### TECHNICAL FIELD

A technique according to the present disclosure (hereinafter also referred to as “present technique”) relates to a semiconductor device, a solid-state imaging device, and a method for manufacturing the semiconductor device.

### BACKGROUND ART

A conventionally known semiconductor device can improve embeddability around a wiring part provided on a substrate (e.g., see PTL 1).

### CITATION LIST

### Patent Literature

### [PTL 1]

JP H05-90536A

### SUMMARY

### Technical Problem

A recent semiconductor device is expected to improve embeddability around an element part provided on a substrate.

A main object of the present technique is to provide a semiconductor device that can improve embeddability around an element part provided on a substrate.

### Solution to Problem

The present technique provides a semiconductor device including:
a substrate; and
at least one element part provided on the substrate,
wherein
at least a part of the element part is shaped to increase in width toward the substrate, the part including a side opposite to a side near the substrate.

The semiconductor device may further include an embedded layer that is embedded around the element part.

A part of the element part may be shaped to increase in width toward the substrate, the part including the side opposite to the side near the substrate.

The element part may be entirely shaped to increase in width toward the substrate.

Each of the element part may include a wiring layer disposed on the substrate and a semiconductor layer disposed on the wiring layer, and at least a part of the semiconductor layer may be shaped to increase in width toward the substrate, the part including a side opposite to a side near the substrate.

The semiconductor layer may be entirely shaped to increase in width toward the substrate, and at least a part of the wiring layer may be shaped to increase in width toward the substrate, the part including a side near the semiconductor layer.

The semiconductor device may further include a protective film covering at least a part of the element part.

Each of the element part may include a wiring layer disposed on the substrate, a semiconductor layer disposed on the wiring layer, and a side wall provided at least near the sides of the semiconductor layer, the side wall being shaped to increase in width toward the substrate.

The side wall may be a part of the protective film covering the semiconductor layer, the wiring layer, and the substrate.

The semiconductor device may further include a protective film covering the semiconductor layer, the wiring layer, and the substrate, and the side wall may be provided on the sides of the semiconductor layer and the wiring layer with the protective film interposed between the side of the semiconductor layer and the side wall.

The side wall may be made of an inorganic material.

The side wall may be made of a SiN material.

The widest part of the side wall may have a width of 450 nm or more in an in-plane direction.

The shape may be a tapered shape.

The embedded layer may be made of an inorganic material.

The substrate may include a semiconductor substrate, and a wiring layer disposed on the semiconductor substrate.

The at least one element part may be a plurality of element parts.

Each of the element part may be any one of a memory element, a logic element, an analog element, an interface element, and an AI element.

The substrate may include at least one of a memory element, a logic element, an analog element, an interface element, and an AI element.

The substrate may include a pixel part having a photoelectric conversion element, and the element part may process a signal outputted from the substrate.

The present technique also provides a solid-state imaging device including: another substrate including a pixel part having a photoelectric conversion element; and
the semiconductor device that processes a signal outputted from the substrate.

The present technique also provides a method for manufacturing a semiconductor device, the method including:
bonding an element chip to a substrate;
forming an inorganic film on the element chip and the substrate; and
forming a side wall near the sides of the element chip by etching the inorganic film, the side wall increasing in width toward the substrate.

The method for manufacturing the semiconductor device may further include forming another inorganic film having a smaller thickness than the inorganic film on the element chip and the substrate, after the bonding and before the film-forming.

The forming may leave a part of the inorganic film covering the substrate in the thickness direction and a part of the inorganic film covering a side of the element chip, the side of the element chip being opposite to a side near the substrate.

The method for manufacturing the semiconductor device may further include embedding an inorganic film around the element chip and the side wall, after the forming.

The method for manufacturing a semiconductor device may further include polishing the inorganic film to planarize the inorganic film after the embedding.

The present technique also provides a method for manufacturing a semiconductor device, the method including: generating an element chip such that at least a part of the element chip is shaped to increase in width from one side, the part of the element chip including the one side in the thickness direction;
bonding a substrate to a side of the element chip, the side of the element chip being opposite to the one side of the element.

In the generating, the element chip may be generated by dicing a laminate including at least the semiconductor layer and the wiring layer.

The method for manufacturing a semiconductor device may further include embedding an inorganic film around the element chip after the generating.

The method for manufacturing a semiconductor device may further include polishing the inorganic film to planarize the film after the embedding.

### BRIEF DESCRIPTION OF DRAWINGS

FIG. 1A is a plan view illustrating a semiconductor device according to example 1 of a first embodiment of the present technique. FIG. 1B is a cross-sectional view illustrating the semiconductor device according to example 1 of the first embodiment of the present technique.

FIG. 2 is an explanatory drawing illustrating the shape of a side wall in the semiconductor device of FIG. 1.

FIG. 3 is a flowchart for explaining an example of a method for manufacturing the semiconductor device of FIG. 1.

FIGS. 4A to 4C are cross-sectional views illustrating the steps of the method for manufacturing the semiconductor device of FIG. 1.

FIGS. 5A to 5C are cross-sectional views illustrating the steps of the method for manufacturing the semiconductor device of FIG. 1.

FIGS. 6A and 6B are explanatory drawings illustrating a drawback of a semiconductor device according to a comparative example.

FIG. 7 is a cross-sectional view of a semiconductor device according to example 2 of the first embodiment of the present technique.

FIG. 8 is a cross-sectional view of a semiconductor device according to example 3 of the first embodiment of the present technique.

FIG. 9 is a cross-sectional view of a semiconductor device according to example 4 of the first embodiment of the present technique.

FIG. 10 is a cross-sectional view of a semiconductor device according to example 5 of the first embodiment of the present technique.

FIG. 11 is a cross-sectional view of a semiconductor device according to example 6 of the first embodiment of the present technique.

FIG. 12 is a cross-sectional view of a semiconductor device according to example 1 of a second embodiment of the present technique.

FIG. 13 is a flowchart for explaining an example of a method for manufacturing the semiconductor device of FIG. 12.

FIGS. 14A to 14D are cross-sectional views illustrating the steps of the method for manufacturing the semiconductor device of FIG. 12.

FIGS. 15A to 15C are cross-sectional views illustrating the steps of the method for manufacturing the semiconductor device of FIG. 12.

FIG. 16 is a cross-sectional view of a semiconductor device according to example 2 of the second embodiment of the present technique.

FIG. 17 is a cross-sectional view of a semiconductor device according to example 3 of the second embodiment of the present technique.

FIG. 18 is a cross-sectional view of a semiconductor device according to example 4 of the second embodiment of the present technique.

FIG. 19 is a cross-sectional view of a semiconductor device according to example 1 of a third embodiment of the present technique.

FIG. 20 is a flowchart for explaining an example of a method for manufacturing the semiconductor device of FIG. 19.

FIGS. 21A to 21C are cross-sectional views illustrating the steps of the method for manufacturing the semiconductor device of FIG. 19.

FIGS. 22A to 22C are cross-sectional views illustrating the steps of the method for manufacturing the semiconductor device of FIG. 19.

FIG. 23 is a cross-sectional view of a semiconductor device according to example 2 of the third embodiment of the present technique.

FIG. 24 is a cross-sectional view of a semiconductor device according to example 3 of the third embodiment of the present technique.

FIG. 25 is a cross-sectional view of a semiconductor device according to example 4 of the third embodiment of the present technique.

FIG. 26 illustrates an example of use of a solid-state imaging device including the semiconductor device according to the first to third embodiments of the present technique.

FIG. 27 is a functional block diagram illustrating an example of an electronic device according to a fourth embodiment to which the present technique is applied.

FIG. 28 is a block diagram illustrating a schematic configuration example of a vehicle control system.

FIG. 29 is an explanatory drawing illustrating an example of the installation positions of a vehicle external information detection unit and imaging units.

FIG. 30 illustrates a schematic configuration example of an endoscopic surgery system.

FIG. 31 is a block diagram illustrating an example of the functional configuration of a camera head and a CCU.

### DESCRIPTION OF EMBODIMENTS

Preferred embodiments of the present technique will be described in detail with reference to the accompanying drawings. In the present specification and the drawings, components having substantially the same functional configuration will be denoted by the same reference numerals, and thus repeated descriptions thereof will be omitted. The following embodiments illustrate a representative embodiment of the present technique, and the scope of the present technique should not be narrowly interpreted on the basis of the illustration. Even if it is described that multiple effects are obtained by each of a semiconductor device, a solid-state imaging device, and a method for manufacturing the semiconductor device according to the present technique in the present specification, each of the semiconductor device, the solid-state imaging device, and the method for manufacturing the semiconductor device according to the present technique only needs to obtain at least one of the effects. The advantageous effects described in the present specification are merely exemplary and are not limited, and other advantageous effects may be obtained.

The description will be made in the following order.
1-1. Semiconductor Device according to Example 1 of First Embodiment of Present Technique
1-2. Semiconductor Device according to Example 2 of First Embodiment of Present Technique
1-3. Semiconductor Device according to Example 3 of First Embodiment of Present Technique
1-4. Semiconductor Device according to Example 4 of First Embodiment of Present Technique
1-5. Semiconductor Device according to Example 5 of First Embodiment of Present Technique
1-6. Semiconductor Device according to Example 6 of First Embodiment of Present Technique
2-1. Semiconductor Device according to Example 1 of Second Embodiment of Present Technique
2-2. Semiconductor Device according to Example 2 of Second Embodiment of Present Technique
2-3. Semiconductor Device according to Example 3 of Second Embodiment of Present Technique
2-4. Semiconductor Device according to Example 4 of Second Embodiment of Present Technique
3-1. Semiconductor Device according to Example 1 of Third Embodiment of Present Technique
3-2. Semiconductor Device according to Example 2 of Third Embodiment of Present Technique
3-3. Semiconductor Device according to Example 3 of Third Embodiment of Present Technique
3-4. Semiconductor Device according to Example 4 of Third Embodiment of Present Technique
4. Modification Example of Present Technique
5. Example of Use of Electronic Device including Semiconductor Device according to Present Technique
6. Another Example of Use of Electronic Device including Semiconductor Device according to Present Technique
7. Example of Application to Mobile Object
8. Example of Application to Endoscopic Operation System

Hereinafter, the present technique will be described in detail in accordance with some embodiments.

### FIRST EMBODIMENT

Semiconductor devices according to examples 1 to 6 of a first embodiment of the present technique will be described below.

### 1-1. Semiconductor Device according to Example 1 of First Embodiment of Present Technique

A semiconductor device 1-1 according to example 1 of the first embodiment of the present technique will be described below in accordance with the accompanying drawings.

### <<Configuration of Semiconductor Device>>

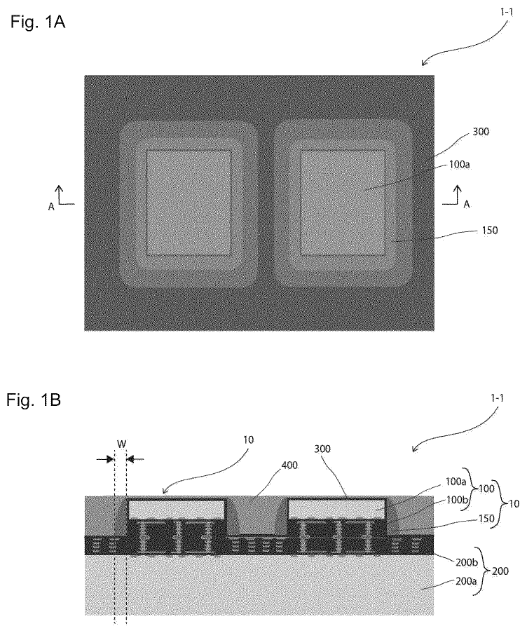

FIG. 1A is a plan view illustrating the semiconductor device 1-1 according to example 1 of the first embodiment of the present technique. FIG. 1B is a cross-sectional view illustrating the semiconductor device 1-1 according to example 1 of the first embodiment of the present technique. FIG. 1B is a cross-sectional view taken along line A-A of FIG. 1A. In cross-sectional views, e.g., FIG. 1B, the upper side will be denoted as the top and the lower side will be denoted as the bottom for convenience.

The semiconductor device 1-1 constitutes, for example, a solid-state imaging device (image sensor). The semiconductor device 1-1 constitutes, for example, a back-illuminated solid-state imaging device that is irradiated with light from the back side of a substrate 200, which will be described later.

As illustrated in FIG. 1B, the semiconductor device 1-1 includes, for example, the substrate 200 and at least one (for example, a plurality of) element part 10 provided on the substrate 200. The semiconductor device 1-1 may further include, for example, an embedded layer 400 that is embedded around the element part 10.

### (Substrate 200)

The substrate 200 includes, for example, a pixel part having a photoelectric conversion element. The pixel part includes, for example, a plurality of pixels arranged in a two-dimensional array. Each of the pixels includes at least one photoelectric conversion element. The substrate 200 includes a semiconductor substrate 200a and a wiring layer 200b disposed on the semiconductor substrate 200a.

The semiconductor substrate 200a is, for example, a Si substrate, a Ge substrate, a GaAs substrate, or a InGaAs substrate. The semiconductor substrate 200a includes, for example, a plurality of pixels, each having a photoelectric conversion element. The photoelectric conversion element is, for example, a PD (photodiode). Each pixel may have a color filter on the back side (a side opposite to the wiring layer 200b) of the semiconductor substrate 200a. Each pixel may have a microlens on the back side of the semiconductor substrate 200a or the color filter.

The wiring layer 200b is, for example, a multilayer wiring layer in which internal wirings are provided in multiple layers in an insulating film, and may be a single-layer wiring layer in which an internal wiring is provided in a single layer in an insulating film. In the wiring layer 200b, the internal wiring is made of, for example, copper (Cu), aluminum (Al), or tungsten (W). The insulating film is configured with, for example, a silicon oxide film or a silicon nitride film.

The substrate 200 further includes, for example, a control circuit (analog element) that controls a plurality of pixels, and an A/D converter (analog element) that performs A/D conversion on an electric signal (analog signal) outputted from the pixel part.

The control circuit includes, for example, circuit elements such as a transistor. Specifically, the control circuit includes, for example, a plurality of pixel transistors (so-called MOS transistors). For example, the plurality of pixel transistors may include three transistors: a transfer transistor, a reset transistor, and an amplifier transistor. Alternatively, the plurality of pixel transistors may include four transistors, further including a selection transistor. The equivalent circuit of a unit pixel is identical to an ordinary equivalent circuit, and thus a detailed description thereof is omitted. The pixel may be configured as a unit pixel. Moreover, the pixel may have a shared pixel structure. The pixel shared structure is a structure in which a plurality of photodiodes share floating diffusion constituting a transfer transistor and transistors other than the transfer transistor.

### (Element Part)

The plurality of element parts 10 include, for example, a logic element as one element part 10 and memory elements as other element parts 10. The plurality of element parts 10 are arranged on the substrate 200.

In the one element part 10 (logic element), for example, a logic circuit is provided in a semiconductor layer 100a, and the logic circuit is electrically connected to the internal wiring of a wiring layer 100b. The logic circuit processes a digital signal obtained by performing, through the A/D converter, A/D conversion on an analog signal outputted from the pixel part.

In the other element parts 10 (memory elements), for example, a memory circuit is provided in the semiconductor layer 100a, and the memory circuit is electrically connected to the internal wiring of the wiring layer 100b. The memory circuit temporarily stores and holds a digital signal obtained by performing, through the A/D converter, A/D conversion on an analog signal outputted from the pixel part, and then outputs the digital signal to the logic circuit. The memory circuit can also temporarily store and hold a digital signal being processed in the logic circuit and/or a processed digital signal.

As illustrated in FIG. 1B, at least a part of the element part 10 is shaped to increase in width toward the substrate 200, the part including a side opposite to a side near the substrate 200. For example, the element part 10 is entirely shaped to increase in width toward the substrate 200.

The element part 10 includes, for example, the wiring layer 100b disposed on the substrate 200 and the semiconductor layer 100a disposed on the wiring layer 100b. The wiring layer 100b is bonded (e.g., metallic bonding) to face the wiring layer 200b.

The semiconductor layer 100a and the wiring layer 100b of the element part 10 constitute an element chip 100. The element part 10 further includes a protective film 300 covering the element chip 100. The protective film 300 is provided (e.g., like a rectangular pulse) along the element chips 100 and the wiring layer 200b. The thickness of the protective film 300 is, for example, about several hundreds nanometers. For example, in the element chip 100, the semiconductor layer 100a and the wiring layer 100b are both rectangular in cross section. The overall element chip 100 is also rectangular in cross section. The element chips 100 of the element parts 10 may be identical or different in size.

The element part 10 further includes a side wall 150 provided near the sides of the semiconductor layer 100a and the wiring layer 100b.

For example, the side wall 150 is shaped to increase in width toward the substrate 200. The side wall 150 is provided on, for example, the sides of the semiconductor layer 100a and the wiring layer 100b of the element chip 100 with the protective film 300 interposed therebetween.

The side wall 150 is made of, for example, an inorganic material. Specifically, the side wall 150 can be made of a SiN (e.g., SiNx), SiO (e.g., SiOx), SiON, SiCN, or SiOC inorganic material. In view of reliability, the side wall 150 is preferably made of a SiN material.

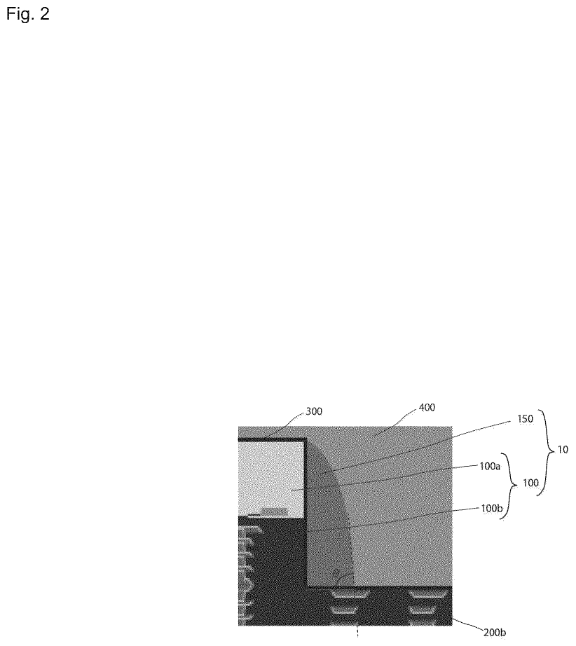

It is preferable that a tangent line at the widest part of the side wall 150 in the in-plane direction forms an angle θ (see FIG. 2) of 88° or less with respect to the top surface of the substrate 200 (specifically, the top surface of the wiring layer 200b).

The widest part of the side wall 150 preferably has a width W of 450 nm or more in the in-plane direction. It is found that the entry of moisture or dust into the element chip 100 can be sufficiently suppressed particularly when the width W is 450 nm or more.

### (Embedded Layer)

For example, the embedded layer 400 is embedded around the element parts 10 and covers the top surfaces of the element parts 10. The top surface of the embedded layer 400 is an evenly flat surface.

The embedded layer 400 is made of, for example, an inorganic material. Specifically, the embedded layer 400 is made of a SiN (e.g., SiNx), SiO (e.g., SiOx), SiON, SiCN, or SiOC inorganic material.

### <<Operations of Semiconductor Device>>

The operations of the semiconductor device 1-1 according to example 1 of the first embodiment of the present technique will be described below.

Digital signals obtained by performing A/D conversion on analog signals outputted from the pixel parts are temporarily stored and held in the memory circuits and then are sequentially outputted to the logic circuit. The logic circuit processes the transmitted digital signals. The digital signal can also be temporarily stored and held in the memory circuit during and/or after processing in the logic circuit.

### <<Method for Manufacturing Semiconductor Device>>

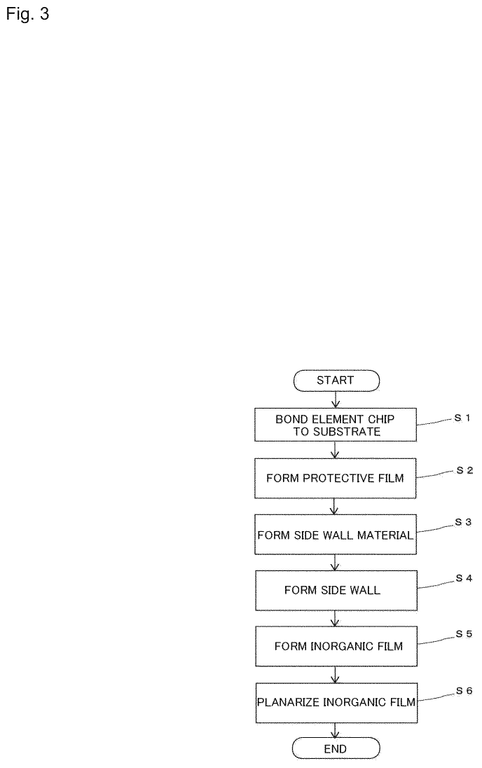

The semiconductor device 1-1 according to example 1 of the first embodiment of the present technique will be described below with reference to the flowchart of FIG. 3 and FIGS. 4A to 5C.

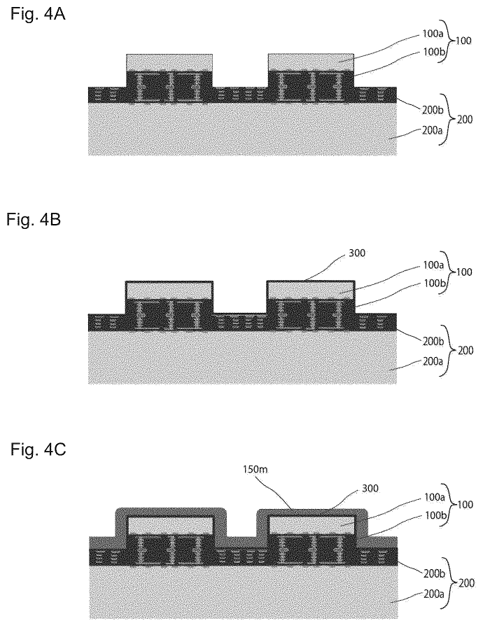

In first step S1, the element chips 100 are bonded to the substrate 200. Specifically, the wiring layer 200b of the substrate 200 and the wiring layer 100b of the element chip 100 of the element part 10 are bonded face-to-face by, for example, metallic bonding (see FIG. 4A). The substrate 200 is generated by forming the wiring layer 200b on a surface of the semiconductor substrate 200a near the pixel part by photolithography after the pixel part is formed on the semiconductor substrate 200a by photolithography. The element chip 100 of the one element part 10 (logic element) is generated by forming the logic circuit on a wafer, which serves as the substrate of the semiconductor layer 100a, by photolithography, forming a wiring layer as the substrate of the wiring layer 100b on the wafer, and then dividing the wafer into chips by dicing. The element chips 100 of the other element parts 10 (memory elements) are generated by forming memory circuits on the wafer, which serves as the substrate of the semiconductor layer 100a, by photolithography, forming the wiring layer as the substrate of the wiring layer 100b on the wafer, and then dividing the wafer into chips by dicing.

In next step S2, the protective film 300 is formed. Specifically, the protective film 300 is formed to cover the plurality of element chips 100 and the exposed surface of the wiring layer 200b of the substrate 200 (see FIG. 4B).

In next step S3, a side-wall material 150m is formed. Specifically, the side-wall material 150m, which is a material of the side wall 150, is formed to cover the protective film 300 (see FIG. 4C).

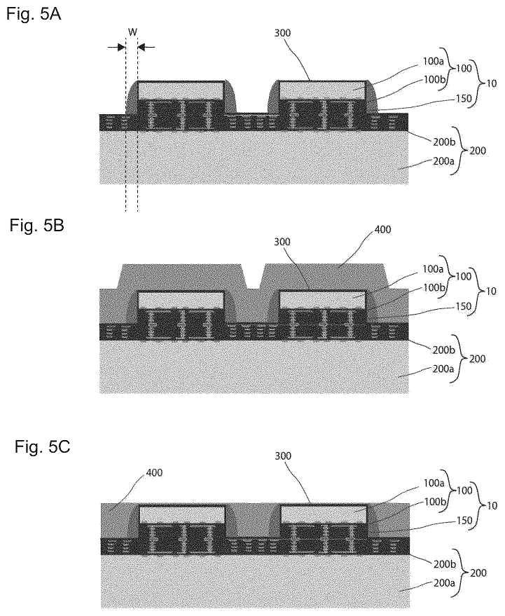

In the next step S4, the side wall 150 is formed (FIG. 5A). Specifically, a part to be formed into the side wall 150 in the side-wall material 150m formed on the protective film 300 is masked with, for example, a resist, and then a part other than the masked part is removed by etching, e.g., dry etching. At this point, the part is preferably etched such that the width W of the widest part of the side wall 150 in the in-plane direction is 450 nm or more and/or θ is 88° or less.

In next step S5, an embedded material 400m (e.g., an inorganic film) that is a material of the embedded layer 400 is formed (see FIG. 5B). Specifically, the embedded material 400m is formed to be embedded around the element part 10, in which the side wall 150 is formed on the element chip 100. At this point, on the embedded material 400m, a step in a relatively simple shape is formed at a position corresponding to a corner of the element chip 100.

In last step S6, the embedded material 400m (e.g., an inorganic film) is planarized. Specifically, for example, the embedded material 400m is polished by using, for example, a CMP (Chemical Mechanical Polisher) until steps are removed. As a result, the embedded layer 400 is generated with uniform planarization.

### <<Effects of Semiconductor Device and Method for Manufacturing Semiconductor Device>>

The effects of the semiconductor device 1-1 according to example 1 of the first embodiment of the present technique will be described below.

The semiconductor device 1-1 according to example 1 includes the substrate 200 and the at least one element part 10 provided on the substrate 200. At least a part of the element part 10 is shaped to increase in width toward the substrate 200, the part including a side opposite to a side near the substrate 200. According to the semiconductor device 1-1, the semiconductor device can be provided with enhanced embeddability around the element part 10 provided on the substrate 200.

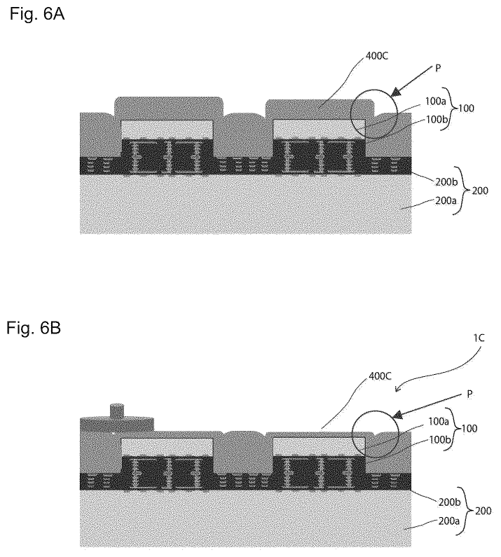

In a semiconductor device 1C according to a comparative example illustrated in FIG. 6B, an element part is configured only with an element chip 100 rectangular in cross section. In this case, when an embedded material 400Cm (e.g., an inorganic film) that is a material of an embedded layer 400C is formed, a part corresponding to a corner of the element chip 100 in the embedded material 400Cm is reduced in thickness (as indicated by an arrow P in FIG. 6A, a fanglike shape sharply dented toward a corner of the element chip 100). Even if the surface of the embedded material 400Cm is polished, the sharp dent is left and interferes with uniform planarization (see a portion indicated by the arrow P in FIG. 6B). Thus, another film needs to be formed. The material of the embedded material 400Cm may be formed with a large thickness and planarized by polishing until the sharp dent is removed. However, an extremely large thickness may cause large warpage or film cracks.

It is preferable that the semiconductor device 1-1 further includes the embedded layer 400 that is embedded around the element parts 10. Thus, the embedded layer 400 can be obtained with uniform planarization. In this case, a joint interface can be properly formed when the embedded layer 400 and other members (e.g., a circuit board, a heatsink, a memory substrate, an AI substrate, and an interface substrate) are bonded to each other. For example, also when a Si substrate is bonded on the embedded layer 400, the semiconductor device 1-1 is effective in forming a proper joint interface.

The element part 10 may be entirely shaped to increase in width toward the substrate 200.

It is preferable to further provide the protective film 300 covering at least a part (e.g., the element chip 100) of the element part 10 and the substrate 200. This can suppress the entry of moisture or dust into the element chip 100.

The element part 10 may include the wiring layer 100b disposed on the substrate 200, the semiconductor layer 100a disposed on the wiring layer 100b, and the side wall 150 provided at least near the sides of the semiconductor layer 100a (for example, the sides of the element chip 100), the side wall 150 being shaped to increase in width toward the substrate 200. In this case, the entry of moisture or dust into the element chip 100 can be suppressed.

The side wall 150 may be made of an inorganic material. It is particularly preferable that the side wall 150 is made of a SiN material.

The widest part of the side wall 150 preferably has a width W of 450 nm or more in the in-plane direction.

The protective film 300 covering the semiconductor layer 100a, the wiring layer 100b, and the substrate 200 is further provided, and the side wall 150 is provided on the sides of the semiconductor layer 100a and the wiring layer 100b (the sides of the element chip 100) with the protective film 300 interposed therebetween. This can double protection for the sides of the element chip 100, thereby sufficiently suppressing the entry of moisture or dust into the element chip 100.

The embedded layer 400 may be made of an inorganic material.

The substrate 200 may include the semiconductor substrate 200a and the wiring layer 200b disposed on the semiconductor substrate 200a. In this case, for example, the substrate 200 may be provided with a pixel part.

The element part 10 may include a memory element and a logic element. In this case, a semiconductor device (solid-state imaging device) can be obtained with a two-layer structure in which the memory element and the logic element disposed in the in-plane direction and the pixel part are stacked.

The at least one element part 10 may be a plurality of element parts 10. In this case, embeddability between the element parts 10 can be improved by the embedded layer 400.

The method for manufacturing the semiconductor device 1-1 includes the steps of bonding the element chips 100 to the substrate 200, forming an inorganic film on the element chips 100 and the substrate 200, and forming the side wall 150 near the sides of the element chip 100 by etching the inorganic film, the side wall 150 increasing in width toward the substrate 200. According to the method for manufacturing the semiconductor device 1-1, the semiconductor device can be manufactured with enhanced embeddability around the element parts 10 provided on the substrate 200.

The method for manufacturing the semiconductor device 1-1 preferably includes the step of forming another inorganic film having a smaller thickness than the inorganic film on the element chip 100 and the substrate 200, after the bonding step and before the film-forming step. Thus, the semiconductor device 1-1 can be manufactured with a structure that doubles protection for the element chips 100.

It is preferable that the method for manufacturing the semiconductor device 1-1 further includes the step of embedding the embedded material 400m (e.g., an inorganic film) around the element chip 100 and the side wall 150 after the forming step.

It is preferable that the method for manufacturing the semiconductor device 1-1 further includes the step of polishing the embedded material 400m to planarize the material after the embedding step. Thus, the embedded layer 400 can be generated with uniform planarization.

### 1-2. Semiconductor Device according to Example 2 of First Embodiment of Present Technique

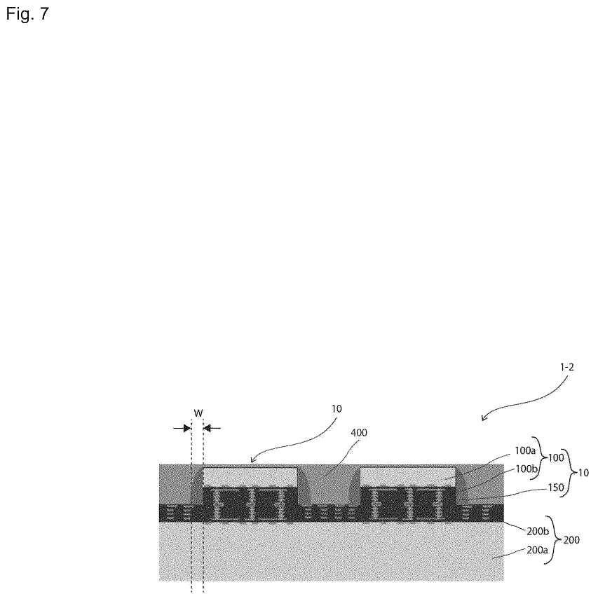

A semiconductor device 1-2 according to example 2 of the first embodiment of the present technique will be described below in accordance with the accompanying drawings. FIG. 7 is a cross-sectional view of the semiconductor device 1-2.

As illustrated in FIG. 7, the semiconductor device 1-2 has the same configuration as the semiconductor device 1-1 according to example 1 except for the absence of the protective film 300.

The semiconductor device 1-2 performs the same operations as the semiconductor device 1-1 according to example 1 and can be manufactured according to substantially the same manufacturing method.

The semiconductor device 1-2 is inferior to the semiconductor device 1-1 according to example 1 in terms of protective properties for the element chips 100 but can achieve a simplified configuration and reduce the number of manufacturing steps.

### 1-3. Semiconductor Device according to Example 3 of First Embodiment of Present Technique

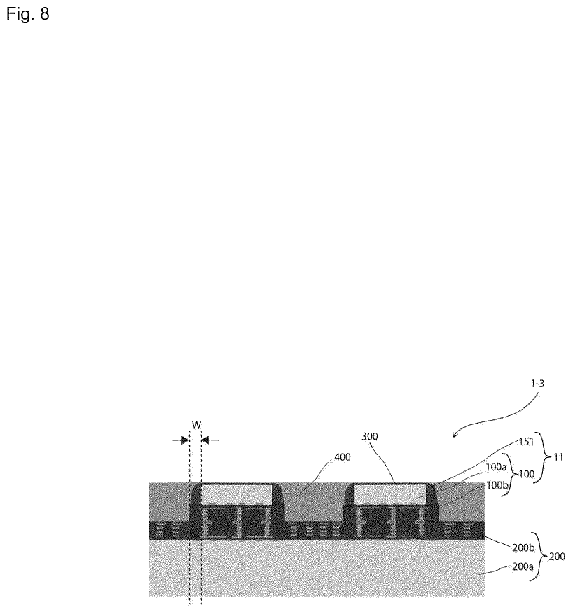

A semiconductor device 1-3 according to example 3 of the first embodiment of the present technique will be described below in accordance with the accompanying drawings. FIG. 8 is a cross-sectional view of the semiconductor device 1-3.

As illustrated in FIG. 8, the semiconductor device 1-3 according to example 3 has the same configuration as the semiconductor device 1-1 according to example 1 except that a part of an element part 11 including the semiconductor layer 100a, the wiring layer 100b, and a side wall 151 is shaped to increase in width toward the substrate 200, the part (side wall 151) including a side opposite to the substrate 200.

To be specific, in the semiconductor device 1-3, the semiconductor layer 100a of the element chip 100 is smaller than the wiring layer 100b and the side wall 151 is provided only near the sides of the semiconductor layer 100a of the element chip 100.

The semiconductor device 1-3 performs the same operations as the semiconductor device 1-1 according to example 1 and can be manufactured according to substantially the same manufacturing method.

The semiconductor device 1-3 is inferior to the semiconductor device 1-1 according to example 1 in terms of protective properties for the wiring layer 100b but can reduce the size of the element part 11 and achieve a high degree of integration.

### 1-4. Semiconductor Device according to Example 4 of First Embodiment of Present Technique

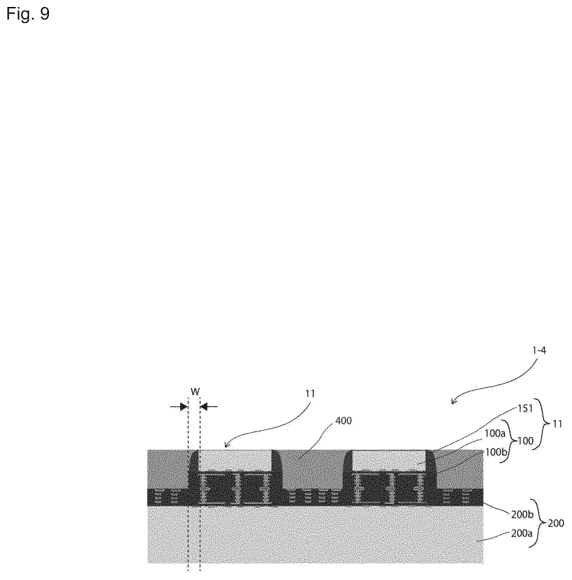

A semiconductor device 1-4 according to example 4 of the first embodiment of the present technique will be described below in accordance with the accompanying drawings. FIG. 9 is a cross-sectional view of the semiconductor device 1-4.

As illustrated in FIG. 9, the semiconductor device 1-4 has the same configuration as the semiconductor device 1-3 according to example 3 except for the absence of the protective film 300.

The semiconductor device 1-4 performs the same operations as the semiconductor device 1-3 according to example 3 and can be manufactured according to substantially the same manufacturing method.

The semiconductor device 1-4 is inferior to the semiconductor device 1-3 according to example 3 in terms of protective properties for the element chips 100 but can achieve a simplified configuration and reduce the number of manufacturing steps.

### 1-5. Semiconductor Device according to Example 5 of First Embodiment of Present Technique

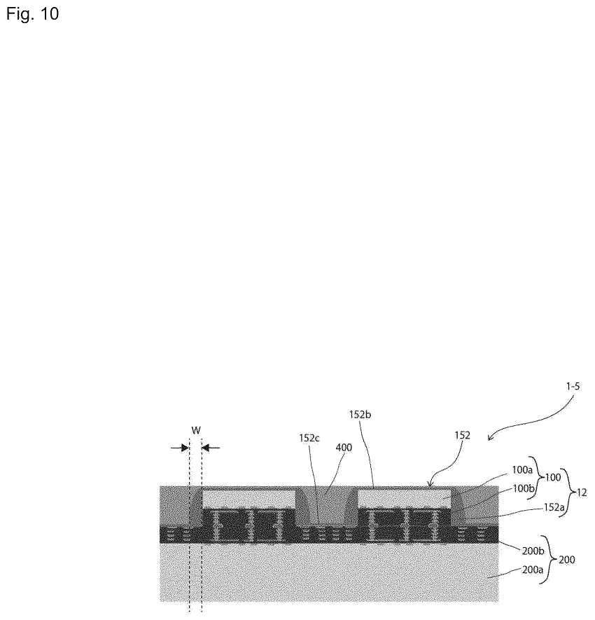

A semiconductor device 1-5 according to example 5 of the first embodiment of the present technique will be described below in accordance with the accompanying drawings. FIG. 10 is a cross-sectional view of the semiconductor device 1-5.

As illustrated in FIG. 10, the semiconductor device 1-5 has the same configuration as the semiconductor device 1-2 according to example 2 except that a side wall 152a is a part of a protective film 152 covering the semiconductor layer 100a, the wiring layer 100b, and the substrate 200.

The protective film 152 includes a part 152b covering the top surface of the element chip 100 and a part 152c covering the top surface (specifically, the top surface of the wiring layer 200b) of the substrate 200, in addition to the side wall 152a. The protective film 152 can be made of, for example, a SiN (e.g., SiNx), SiO (e.g., SiOx), SiON, SiCN, or SiOC inorganic material.

The semiconductor device 1-5 performs the same operations as the semiconductor device 1-2 according to example 2 and can be manufactured according to the same manufacturing method except that a part other than the side wall 152a of the protective film 152 is also left by etch back.

The semiconductor device 1-5 is superior to the semiconductor device 1-2 according to example 2 in terms of protective properties for the semiconductor layer 100a and the wiring layer 200b.

### 1-6. Semiconductor Device according to Example 6 of First Embodiment of Present Technique

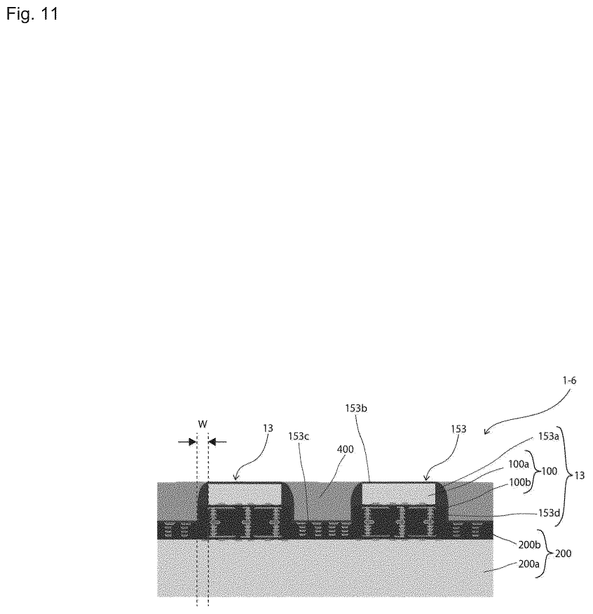

A semiconductor device 1-6 according to example 6 of the first embodiment of the present technique will be described below in accordance with the accompanying drawings. FIG. 11 is a cross-sectional view of the semiconductor device 1-6.

As illustrated in FIG. 11, the semiconductor device 1-6 has the same configuration as the semiconductor device 1-4 according to example 4 except that a side wall 153a is a part of a protective film 153 covering the semiconductor layer 100a, the wiring layer 100b, and the substrate 200.

The protective film 153 includes a part 153b covering the top surface of the element chip 100 and a part 153c covering the top surface (specifically, the top surface of the wiring layer 200b) of the substrate 200, in addition to the side wall 153a. The protective film 153 can be made of, for example, a SiN (e.g., SiNx), SiO (e.g., SiOx), SiON, SiCN, or SiOC inorganic material.

The semiconductor device 1-6 performs the same operations as the semiconductor device 1-4 according to example 4 and can be manufactured according to the same manufacturing method except that a part other than the side wall 153a of the protective film 153 is also left by etch back.

The semiconductor device 1-6 is superior to the semiconductor device 1-4 according to example 4 in terms of protective properties for the semiconductor layer 100a and the wiring layer 200b.

### SECOND EMBODIMENT

Semiconductor devices according to examples 1 to 4 of a second embodiment of the present technique will be described below.

### 2-1. Semiconductor Device according to Example 1 of Second Embodiment of Present Technique

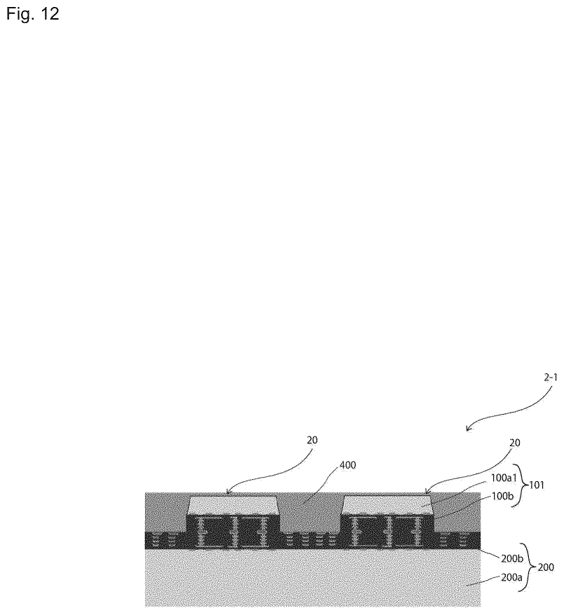

A semiconductor device 2-1 according to example 1 of the second embodiment of the present technique will be described below in accordance with the accompanying drawings. FIG. 12 is a cross-sectional view of the semiconductor device 2-1.

As illustrated in FIG. 12, an element part 20 is configured with an element chip 101 including a semiconductor layer 100a1 and a wiring layer 100b in the semiconductor device 2-1 and has the same configuration as the semiconductor device 1-2 according to example 2 of the first embodiment except that a part of the element part 20 is shaped to increase in width toward a substrate 200, the part including a side opposite to a side near the substrate 200.

The semiconductor layer 100a1 is entirely shaped to increase in width toward the substrate 200. To be specific, the semiconductor layer 100a1 has a tapered shape that increases in width toward the substrate 200. The cone angle (an angle corresponding to θ mentioned above) of the semiconductor layer 100a1 is preferably 88° or less.

### <<Method for Manufacturing Semiconductor Device>>

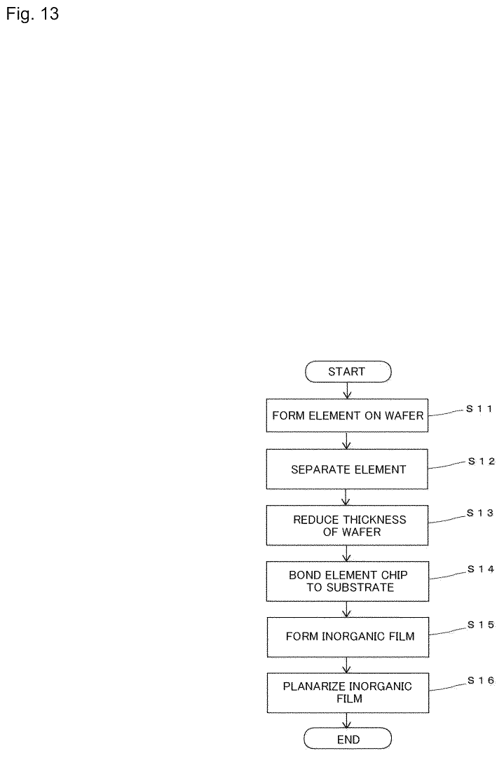

The semiconductor device 2-1 according to example 1 of the second embodiment of the present technique will be described below with reference to the flowchart of FIG. 13 and FIGS. 14A to 15C.

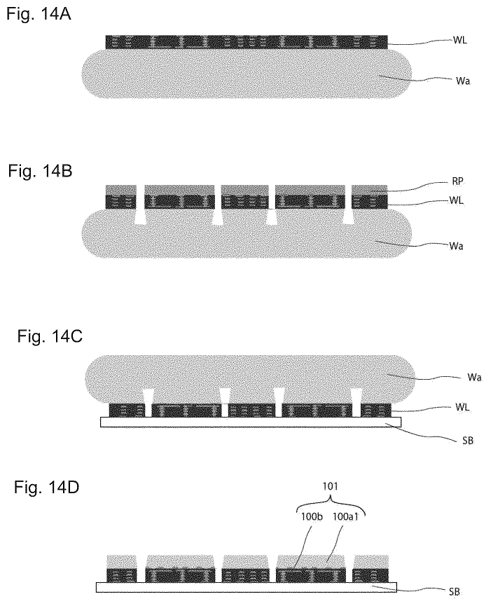

In first step S11, elements (e.g., a logic circuit and memory circuits) are formed on a wafer Wa serving as the substrate of the semiconductor layer 100a1. Specifically, the logic circuit and the memory circuits are first formed on the wafer Wa by photolithography. Subsequently, on a surface of the wafer Wa and near the logic circuit and the memory circuits, a wiring layer WL serving as the substrate of the wiring layer 100b is formed to generate a laminate (see FIG. 14A).

In next step S12, the elements are separated. Specifically, first, a resist pattern RP for forming the element chips 101 is formed on the wiring layer WL of the laminate. The laminate is then half-cut from the wiring layer WL by plasma dicing with the resist pattern RP serving as a mask (see FIG. 14B). At this point, dicing is performed such that the wafer Wa has tapering portions near the wiring layer WL. A region removed by dicing is a region where the element is not formed on one side of the element chip 101, thereby exerting no impacts on the functions of the element chip 101. Thereafter, the resist pattern RP is removed.

In next step S13, the wafer Wa is reduced in thickness. Specifically, first, the wiring layer WL of the laminate is supported by a support substrate SB (see FIG. 14C), and a surface of the wafer Wa is polished by, for example, a CMP (Chemical Mechanical Polisher), the surface being opposite to the wiring layer WL (see FIG. 14D). At this point, the wafer is polished until the element chips 101 are exposed.

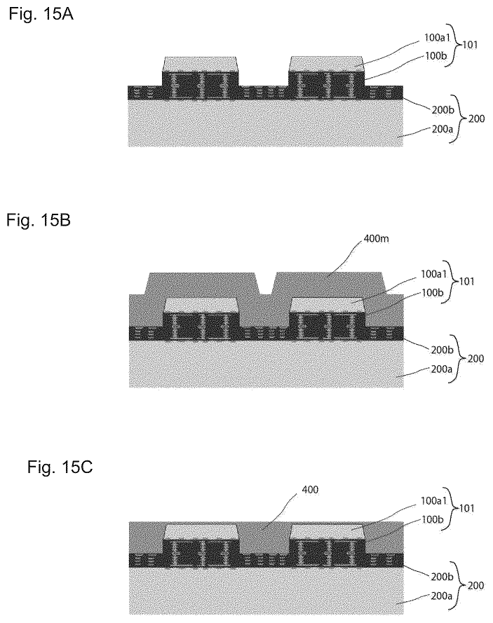

In next step S14, the element chips 101 are bonded to the substrate 200 (see FIG. 15A). Specifically, the wiring layer 100b of the element chip 101 and a wiring layer 200b of the substrate 200 are bonded face-to-face by, for example, metallic bonding. The substrate 200 is generated by, for example, forming the wiring layer 200b on a surface of the semiconductor substrate 200a and near the pixel part by photolithography after forming the pixel part on the semiconductor substrate 200a by photolithography.

In next step S15, an embedded material 400m (e.g., an inorganic film) is formed (see FIG. 15B). Specifically, the embedded material 400m is formed to be embedded around the element chips 101. At this point, on the embedded material 400m, a step in a relatively simple shape is formed at a position corresponding to a corner of the element chip 101.

In last step S16, the embedded material 400m is planarized (see FIG. 15C). Specifically, the embedded material 400m is polished by using, for example, a CMP until the steps of the embedded material 400m are removed. As a result, the embedded layer 400 is generated with uniform planarization.

The semiconductor device 2-1 is inferior to the semiconductor device 1-2 according to example 2 of the first embodiment in terms of protective properties for the element chips 101 but can achieve a simplified configuration and reduce the number of manufacturing steps.

A method for manufacturing the semiconductor device 2-1 includes the steps of. generating the element chip 101 such that at least a part (for example, a part) of the element chip is shaped to increase in width from one side, the part including the one side in the thickness direction; and bonding the substrate 200 to a side of the element chip 101, the side being opposite to the one side of the element chip 101. Thus, the semiconductor device 2-1 can be easily manufactured in a short time.

In the generating step, the element chip 101 is generated by dicing the laminate including at least the semiconductor layer 100a and the wiring layer 100b. Thus, the semiconductor device 2-1 can be more easily manufactured.

It is preferable that the method for manufacturing the semiconductor device 2-1 further includes the step of embedding the embedded material 400m around the element chip 101 after the generating step.

It is preferable that the method for manufacturing the semiconductor device 2-1 further includes the step of polishing the embedded material 400m to planarize the material after the embedding step.

### 2-2. Semiconductor Device according to Example 2 of Second Embodiment of Present Technique

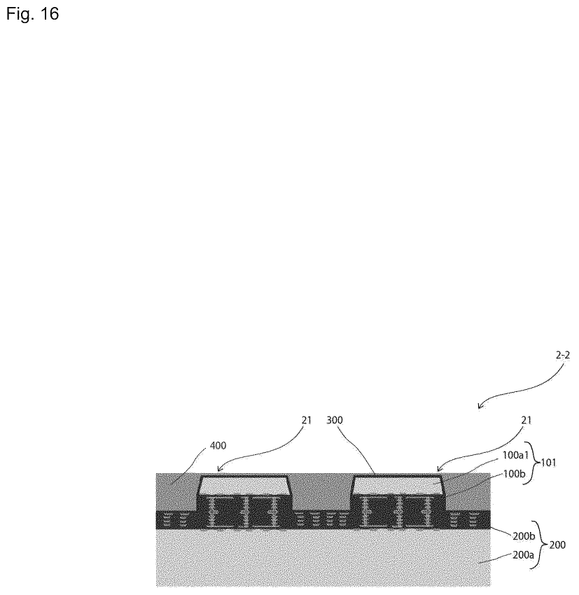

A semiconductor device 2-2 according to example 2 of the second embodiment of the present technique will be described below in accordance with the accompanying drawings. FIG. 16 is a cross-sectional view of the semiconductor device 2-2.

As illustrated in FIG. 16, the semiconductor device 2-2 has the same configuration as the semiconductor device 2-1 according to example 1 except that an element part 21 includes a protective film 300 between the element chip 101 and the embedded layer 400.

The protective film 300 is provided along the surfaces of the element chips 101 and the substrate 200 and near the wiring layer 200b.

The semiconductor device 2-2 performs the same operations as the semiconductor device 2-1 according to example 1 and can be manufactured according to substantially the same manufacturing method.

The semiconductor device 2-2 is superior to the semiconductor device 2-1 according to example 1 in terms of protective properties for the element chips 101 and the wiring layer 200b, though the number of manufacturing steps increases.

### 2-3. Semiconductor Device according to Example 3 of Second Embodiment of Present Technique

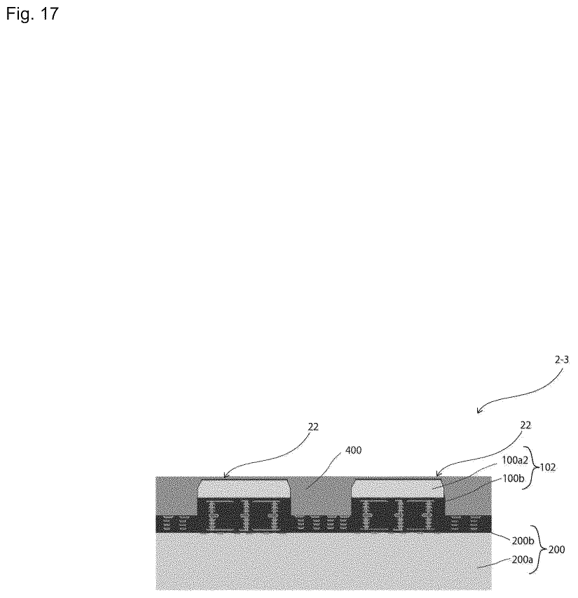

A semiconductor device 2-3 according to example 3 of the second embodiment of the present technique will be described below in accordance with the accompanying drawings. FIG. 17 is a cross-sectional view of the semiconductor device 2-3.

As illustrated in FIG. 17, the semiconductor device 2-3 has the same configuration as the semiconductor device 2-1 according to example 1 except that a part (upper part)of an element part 22 is shaped (for example, tapered)to increase in width toward the substrate 200, the part including a surface of the semiconductor layer 100a2 of an element chip 102, the surface being opposite to the wiring layer 100b. The cone angle (an angle corresponding to θ mentioned above) of the semiconductor layer 100a2 is preferably 88° or less.

The semiconductor device 2-3 performs the same operations as the semiconductor device 2-1 according to example 1 and can be manufactured according to substantially the same manufacturing method.

The semiconductor device 2-3 obtains substantially the same effect as the semiconductor device 2-1 according to example 1.

### 2-4. Semiconductor Device according to Example 4 of Second Embodiment of Present Technique

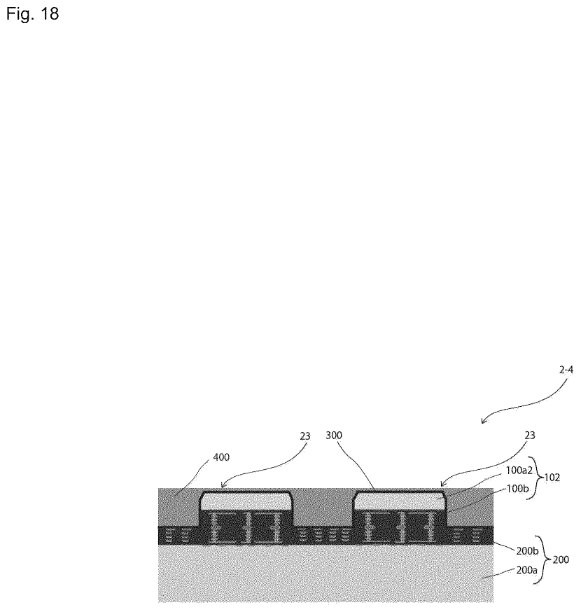

A semiconductor device 2-4 according to example 4 of the second embodiment of the present technique will be described below in accordance with the accompanying drawings. FIG. 18 is a cross-sectional view of the semiconductor device 2-4.

As illustrated in FIG. 18, the semiconductor device 2-2 has the same configuration as the semiconductor device 2-3 according to example 3 except that an element part 23 includes the protective film 300 between the element chip 102 and an embedded layer 400.

The protective film 300 is provided along the surfaces of the element chips 102 and the substrate 200 and near the wiring layer 200b.

The semiconductor device 2-4 performs the same operations as the semiconductor device 2-3 according to example 3 and can be manufactured according to substantially the same manufacturing method.

The semiconductor device 2-4 is superior to the semiconductor device 2-3 according to example 3 in terms of protective properties for the element chips 102, though the number of manufacturing steps increases.

### THIRD EMBODIMENT

Semiconductor devices according to examples 1 to 4 of a third embodiment of the present technique will be described below.

### 3-1. Semiconductor Device according to Example 1 of Third Embodiment of Present Technique

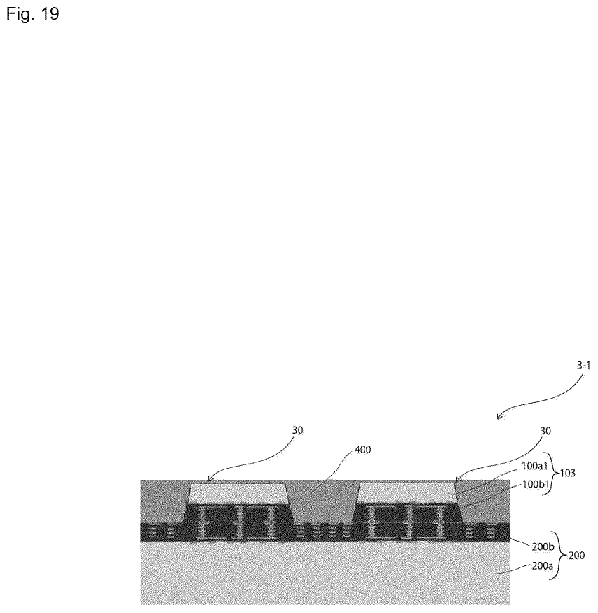

A semiconductor device 3-1 according to example 1 of the third embodiment of the present technique will be described below in accordance with the accompanying drawings. FIG. 19 is a cross-sectional view of the semiconductor device 3-1.

As illustrated in FIG. 19, an element part 30 is configured with an element chip 103 including a semiconductor layer 100a1 and a wiring layer 100b1 in the semiconductor device 3-1 and has the same configuration as the semiconductor device 2-1 according to example 1 of the second embodiment except that the element part 30 is entirely shaped (for example, tapered) to increase in width toward a substrate 200.

For example, the semiconductor layer 100a1 is entirely shaped (for example, tapered)to increase in width toward the substrate 200, and at least a part of the wiring layer 100b1 (for example, the overall wiring layer 100b1) is shaped (for example, tapered) to increase in width toward the substrate 200, the part including a side near the semiconductor layer 100a1. For example, the semiconductor layer 100a1 and the wiring layer 100b1 have the same cone angle with sides flush with each other.

The semiconductor device 3-1 performs the same operations as the semiconductor device 2-1 according to example 1 of the second embodiment.

### <<Method for Manufacturing Semiconductor Device>>

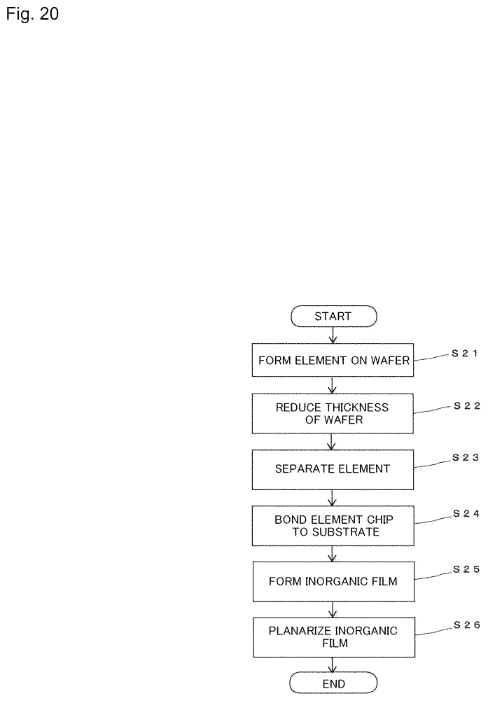

The semiconductor device 3-1 according to example 1 of the third embodiment of the present technique will be described below with reference to the flowchart of FIG. 20 and FIGS. 21A to 22C.

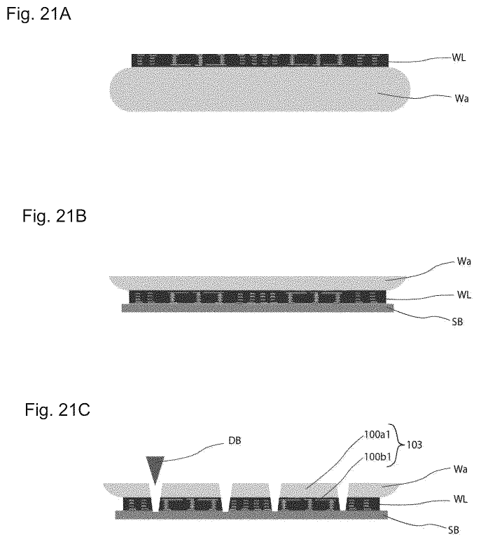

In first step S21, elements (e.g., a logic circuit and memory circuits) are formed on a wafer Wa serving as the substrate of the semiconductor layer 100a1. Specifically, the logic circuit and the memory circuits are first formed on the wafer Wa by photolithography. Subsequently, on a surface of the wafer Wa and near the logic circuit and the memory circuits, a wiring layer WL serving as the substrate of the wiring layer 100b is formed to generate a laminate (see FIG. 21A).

In next step S22, the wafer Wa is reduced in thickness (see FIG. 21B). Specifically, first, the laminate is supported by a support substrate SB from the wiring layer WL, and a surface of the wafer Wa is polished by, for example, a CMP (Chemical Mechanical Polisher), the surface being opposite to the wiring layer WL. At this point, the wafer is polished until or right before the logic circuit and the memory circuits are exposed.

In next step S23, the elements are separated (see FIG. 21C). Specifically, a wedge-shaped dicing blade DB is pressed from the wafer Wa to dice the laminate. Thus, the element chip 103 is generated with sides formed by the shape of the dicing blade DB.

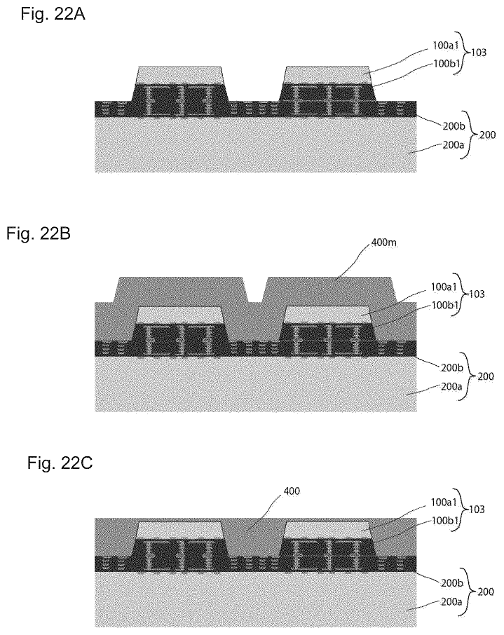

In next step S24, the element chips 103 are bonded to the substrate 200 (see FIG. 22A). Specifically, the wiring layer 100b1 of the element chip 103 and a wiring layer 200b of the substrate 200 are bonded face-to-face by, for example, metallic bonding. The substrate 200 is generated by, for example, forming the wiring layer 200b on a surface of the semiconductor substrate 200a and near the pixel part by photolithography after forming the pixel part on the semiconductor substrate 200a by photolithography.

In next step S25, an embedded material 400m (e.g., an inorganic film) is formed (see FIG. 22B). Specifically, the embedded material 400m is formed to be embedded around the element chips 103. At this point, on the embedded material 400m, a step in a relatively simple shape is generated at a position corresponding to a corner of the element chip 103.

In last step S26, the embedded material 400m (e.g., an inorganic film) is planarized (see FIG. 22C). Specifically, the embedded material 400m is polished by using, for example, a CMP until the steps of the embedded material 400m are removed. As a result, the embedded layer 400 is generated with uniform planarization.

The semiconductor device 3-1 obtains substantially the same effect as the semiconductor device 2-1 according to example 1 of the second embodiment.

### 3-2. Semiconductor Device according to Example 2 of Third Embodiment of Present Technique

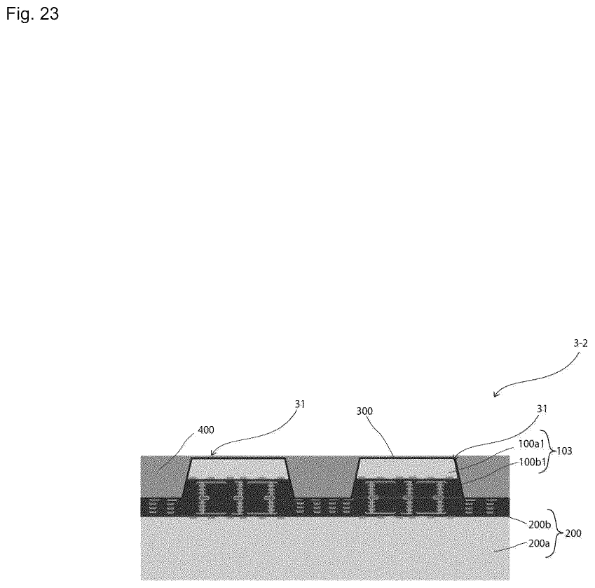

A semiconductor device 3-2 according to example 2 of the third embodiment of the present technique will be described below in accordance with the accompanying drawings. FIG. 23 is a cross-sectional view of the semiconductor device 3-2.

As illustrated in FIG. 23, the semiconductor device 3-2 has the same configuration as the semiconductor device 3-1 according to example 1 except that an element part 31 includes a protective film 300 between the element chip 103 and an embedded layer 400.

The protective film 300 is provided along the surfaces of the element chips 103 and the substrate 200 and near the wiring layer 200b.

The semiconductor device 3-2 performs the same operations as the semiconductor device 3-1 according to example 1 and can be manufactured according to substantially the same manufacturing method.

The semiconductor device 3-2 is superior to the semiconductor device 2-1 according to example 1 in terms of protective properties for the element chips 103, though the number of manufacturing steps increases.

### 3-3. Semiconductor Device according to Example 3 of Third Embodiment of Present Technique

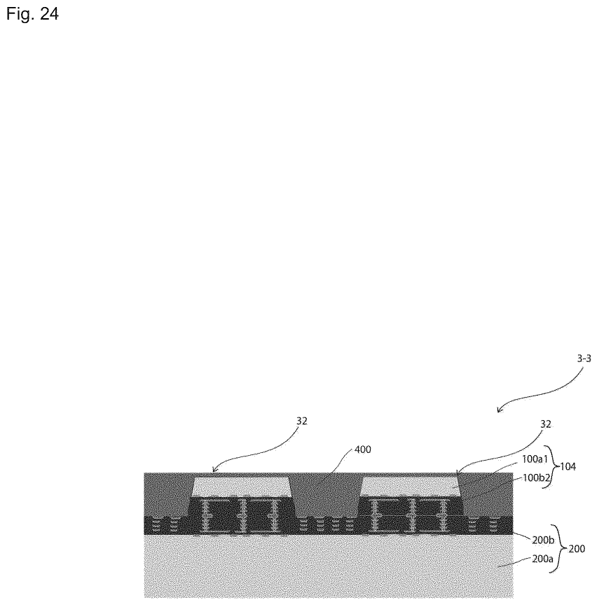

A semiconductor device 3-3 according to example 3 of the third embodiment of the present technique will be described below in accordance with the accompanying drawings. FIG. 24 is a cross-sectional view of the semiconductor device 3-3. The semiconductor device 3-3 has the same configuration as the semiconductor device 3-1 according to example 1 except that a part (upper part) of a wiring layer 100b2 of an element chip 104 is shaped to increase in width toward the substrate 200, the part including a side opposite to a side near the semiconductor layer 100a1.

The semiconductor device 3-3 performs the same operations as the semiconductor device 3-1 according to example 1 and can be manufactured according to substantially the same manufacturing method. The side shape (only the upper part is tapered) of the wiring layer 100b2 can be obtained by using the dicing blade DB shaped according to the side shape.

The semiconductor device 3-3 obtains substantially the same effect as the semiconductor device 3-1 according to example 1.

### 3-4. Semiconductor Device According to Example 4 of Third Embodiment of Present Technique

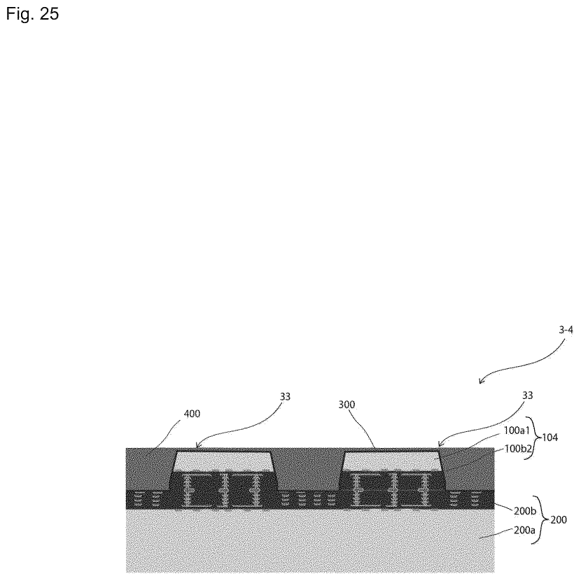

A semiconductor device 3-4 according to example 4 of the third embodiment of the present technique will be described below in accordance with the accompanying drawings. FIG. 25 is a cross-sectional view of the semiconductor device 3-4.

As illustrated in FIG. 25, the semiconductor device 3-4 has the same configuration as the semiconductor device 3-3 according to example 3 except that an element part 33 includes a protective film 300 between the element chip 104 and an embedded layer 400.

The protective film 300 is provided along the surfaces of the element chips 104 and the substrate 200 and near the wiring layer 200b.

The semiconductor device 3-4 performs the same operations as the semiconductor device 3-3 according to example 3 and can be manufactured according to substantially the same manufacturing method.

The semiconductor device 3-4 is superior to the semiconductor device 3-3 according to example 3 in terms of protective properties for the element chips 104, though the number of manufacturing steps increases.

### 4. Modification Example of Present Technique

The configurations of the semiconductor devices according to the first to third embodiments can be changed as appropriate.

For example, the configurations of the semiconductor devices according to the examples may be combined with one another within a technically consistent range.

In the semiconductor devices of the examples, the plurality of element parts include the logic element and the memory elements. The configuration is not limited thereto. For example, the plurality of element parts may include at least two elements of a memory element, a logic element, an analog element (e.g., the control circuit or an A/D converter), an interface element, and an AI element having a learning function using an AI (artificial intelligence).

The semiconductor devices of the examples include the plurality of element parts and may include a single element part. In this case, the single element part may be, for example, a memory element, a logic element, an analog element (e.g., the control circuit or an A/D converter), an interface element, or an AI element.

In the semiconductor devices of the examples, the plurality of element parts include different elements (e.g., the logic element and the memory elements) and may include identical elements. In this case, the identical element may be, for example, a memory element, a logic element, an analog element (e.g., the control circuit or an A/D converter), an interface element, or an AI element.

In the semiconductor devices of the examples, the substrate 200 includes the pixel part and may include at least one of a logic element, an analog element, a memory element, an interface element, and an AI element instead of or in addition to the pixel part.

The semiconductor devices of the examples constitute a solid-state imaging device (image sensor) and may include a part (e.g., at least a logic element and an analog element from among a memory element, the logic element, the analog element (e.g., the control circuit or an A/D converter), an interface element, and an AI element) of the solid-state imaging device. In this case, another substrate including the pixel part of the solid-state imaging device and the semiconductor device electrically connected to the pixel part may be integrally configured or may be separately configured.

In the semiconductor devices of the examples, the substrate 200 is provided with the elements. The substrate 200 may be provided without the elements. In this case, the substrate 200 may be, for example, a semiconductor substrate, a semi-insulating substrate, or an insulating substrate.

### 5. Example of Use of Electronic Device including Semiconductor Device according to Present Technique

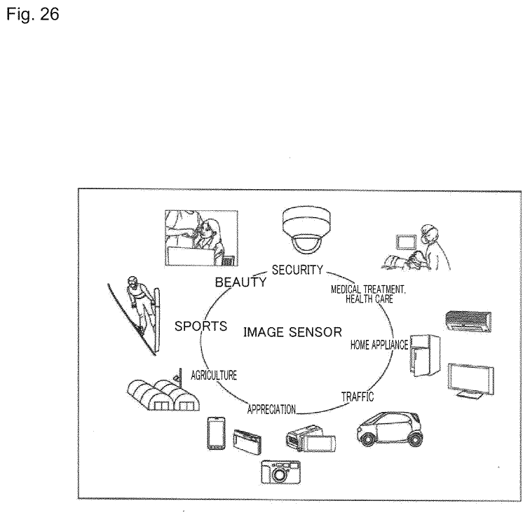

FIG. 26 illustrates an example of use of an electronic device including the semiconductor devices according to the examples of the first to third embodiments of the present technique, the electronic device including a solid-state imaging device (image sensor).

The electronic device can be used in various cases for sensing light such as visible light, infrared light, ultraviolet light, and X-ray as will be described below. Specifically, as shown in FIG. 26, the electronic device can be used for devices used in, for example, the field of appreciation in which an image provided for appreciation is captured, the field of traffic, the field of home appliances, the field of medical treatment and health care, the field of security, the field of beauty, the field of sports, and the field of agriculture.

Specifically, in the field of appreciation, the imaging device, e.g., a digital camera or a smartphone can be used.

In the field of traffic, for safe driving such as automatic stop and recognition of a driver's conditions, the electronic device can be used for devices provided for traffic, for example, an in-vehicle sensor that captures images of the front, rear, surroundings, and inside of a vehicle, a monitoring camera that monitors traveling vehicles and roads, and a distance measuring sensor that measures a distance between vehicles or the like.

In the field of home appliances, the electronic device can be used for devices provided for home appliances such as a television receiver, a refrigerator, and an air conditioner in order to capture an image of a user's gesture and operate equipment in response to the gesture.

In the field of medical treatment and health care, the electronic device can be used for devices provided for medical treatment and health care, for example, an endoscope and a device that performs angiography by receiving infrared light.

In the field of security, the electronic device can be used for devices provided for security, for example, a surveillance camera for crime prevention and a camera for person authentication.

In the field of beauty, the electronic device can be used for devices provided for beauty, for example, a skin measuring instrument that captures images of skins and a microscope that captures images of scalps.

In the field of sports, the electronic device can be used for devices provided for sports, for example, an action camera and a wearable camera for sports applications.

In the field of agriculture, the electronic device can be used for devices provided for agriculture, for example, a camera that monitors the conditions of fields and crops.

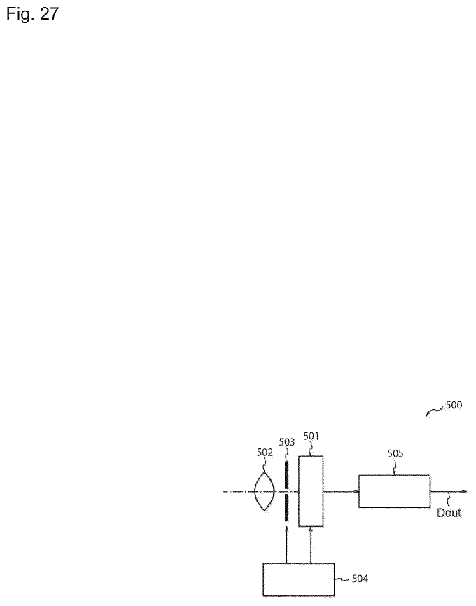

Examples of use of the electronic device will be specifically described below. For example, as an electronic device including the semiconductor devices according to the examples or a solid-state imaging device 501 including the semiconductor devices, the electronic device is applicable to any type of electronic device having an imaging function, e.g., a camera system such as a digital still camera or a video camera, or a mobile phone having an imaging function. FIG. 27 illustrates a schematic configuration of an electronic device 500 (camera) as an example. The electronic device 500 is, for example, a video camera capable of capturing still images or moving images, and includes the solid-state imaging device 501, an optical system (optical lens) 502, a shutter device 503, a drive unit 504 that drives the solid-state imaging device 501 and the shutter device 503, and a signal processing unit 505.

The optical system 502 guides image light (incident light) from a subject to the pixel region of the solid-state imaging device 501. This optical system 502 may be configured with a plurality of optical lenses. The shutter device 503 controls a light irradiation period and a light shielding period for the solid-state imaging device 501. The drive unit 504 controls a transfer operation of the solid-state imaging device 501 and a shutter operation of the shutter device 503. The signal processing unit 505 performs various types of signal processing on signals outputted from the solid-state imaging device 501. A video signal Dout having been subjected to signal processing is stored in a storage medium such as a memory or is outputted to a monitor or the like.

### 6. Another Example of Use of Electronic Device including Semiconductor Device according to Present Technique

An electronic device including the semiconductor devices according to the examples of the first to third embodiments of the present technique, that is, the electronic device including a solid-state imaging device (image sensor) is also applicable to, for example, another electronic device for detecting light, for example, a TOF (Time of Flight) sensor. In application to a TOF sensor, the electronic device is applicable to, for example, a distance image sensor using a direct TOF measuring method or a depth map sensor using an indirect TOF measuring method. In a depth map sensor using the indirect TOF measuring method, the timing of arrival of photons is determined in a direct time domain in each pixel. Thus, an optical pulse is transmitted with a short pulse width, and an electric pulse is generated by a quick response receiver. The present disclosure is applicable to the receiver at that time. Moreover, in the indirect TOF method, a time of flight of light is measured using a semiconductor element structure in which the detection and accumulation amount of a carrier generated by light are changed depending upon the timing of arrival of light. The present disclosure is also applicable as such a semiconductor structure. In application to a TOF sensor, the provision of a color filter array and a microlens array is optional and may not be provided.

### 7. Example of Application to Mobile Object

The technique according to the present disclosure (the present technique) can be applied to various products. For example, the technique according to the present disclosure may be implemented as a device equipped in any type of mobile object such as an automobile, an electric vehicle, a hybrid electric vehicle, a motorcycle, a bicycle, a personal mobility device, an airplane, a drone, a ship, and a robot.

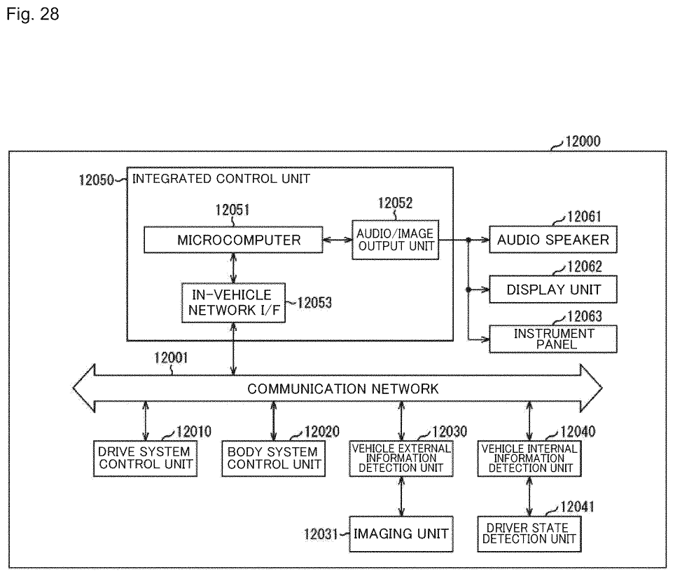

FIG. 28 is a block diagram illustrating a schematic configuration example of a vehicle control system, which is an example of a mobile object control system to which the technique according to the present disclosure can be applied.

The vehicle control system 12000 includes a plurality of electronic control units connected thereto via a communication network 12001. In the example illustrated in FIG. 28, the vehicle control system 12000 includes a drive system control unit 12010, a body system control unit 12020, a vehicle external information detection unit 12030, a vehicle internal information detection unit 12040, and an integrated control unit 12050. In addition, as a functional configuration of the integrated control unit 12050, a microcomputer 12051, an audio/image output unit 12052, and an in-vehicle network interface (I/F) 12053 are illustrated.

The drive system control unit 12010 controls an operation of an apparatus related to a drive system of a vehicle according to various programs. For example, the drive system control unit 12010 functions as a driving force generator for generating a driving force of a vehicle such as an internal combustion engine or a driving motor, a driving force transmission mechanism for transmitting a driving force to wheels, a steering mechanism for adjusting a turning angle of a vehicle, and a control apparatus such as a braking apparatus that generates a braking force of a vehicle.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle external information detection unit 12030 detects information on the outside of the vehicle having the vehicle control system 12000 mounted thereon. For example, an imaging unit 12031 is connected to the vehicle external information detection unit 12030. The vehicle external information detection unit 12030 causes the imaging unit 12031 to capture an image of the outside of the vehicle and receives the captured image. The vehicle external information detection unit 12030 may perform object detection processing or distance detection processing for peoples, cars, obstacles, signs, and letters on the road on the basis of the received image.

The imaging unit 12031 is an optical sensor that receives light and outputs an electrical signal according to the amount of the received light. The imaging unit 12031 can also output the electrical signal as an image or distance measurement information. In addition, the light received by the imaging unit 12031 may be visible light or invisible light such as infrared light.

The vehicle internal information detection unit 12040 detects information on the inside of the vehicle. For example, a driver state detection unit 12041 that detects a driver's state is connected to the vehicle internal information detection unit 12040. The driver state detection unit 12041 includes, for example, a camera that captures an image of a driver, and the vehicle internal information detection unit 12040 may calculate a degree of fatigue or concentration of the driver or may determine whether or not the driver is dozing on the basis of detection information inputted from the driver state detection unit 12041.

The microcomputer 12051 can calculate a control target value of the driving force generation device, the steering mechanism, or the braking device on the basis of the information on the outside or the inside of the vehicle acquired by the vehicle external information detection unit 12030 or the vehicle internal information detection unit 12040 and output a control command to the drive system control unit 12010. For example, the microcomputer 12051 can perform cooperative control for the purpose of obtaining functions of an advanced driver assistance system (ADAS) including collision avoidance or impact mitigation of a vehicle, following traveling based on inter-vehicle distance, vehicle speed maintenance driving, vehicle collision warning, vehicle lane deviation warning, or the like.

Furthermore, the microcomputer 12051 can perform cooperative control for the purpose of automated driving or the like in which autonomous travel is performed without depending on operations of the driver, by controlling the driving force generator, the steering mechanism, or the braking device and the like on the basis of information about the surroundings of the vehicle, the information being acquired by the vehicle external information detection unit 12030 or the vehicle internal information detection unit 12040.

In addition, the microcomputer 12051 can output a control command to the body system control unit 12020 based on the information acquired by the vehicle external information detection unit 12030 outside of the vehicle. For example, the microcomputer 12051 can perform cooperative control for the purpose of preventing glare, such as switching from a high beam to a low beam, by controlling the headlamp according to the position of a vehicle ahead or an oncoming vehicle detected by the vehicle external information detection unit 12030.

The audio/image output unit 12052 transmits an output signal of at least one of sound and an image to an output device capable of visually or audibly notifying a passenger or the outside of the vehicle of information. In the example shown in FIG. 28, as an output device, an audio speaker 12061, a display unit 12062 and an instrument panel 12063 are shown. The display unit 12062 may include, for example, at least one of an onboard display and a head-up display.

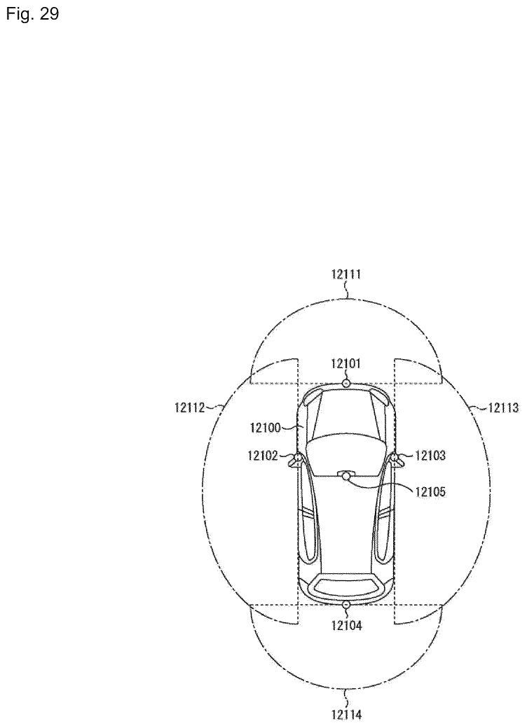

FIG. 29 illustrates an example of the installation position of the imaging unit 12031.

In FIG. 29, a vehicle 12100 includes imaging units 12101, 12102, 12103, 12104, and 12105 as the imaging unit 12031.

The imaging units 12101, 12102, 12103, 12104, and 12105 are provided at positions such as a front nose, side-view mirrors, a rear bumper, a back door, and an upper portion of a windshield in the vehicle 12100. The imaging unit 12101 provided at the front nose and the imaging unit 12105 provided at the upper portion of the windshield in the vehicle mainly acquire images ahead of the vehicle 12100. The imaging units 12102 and 12103 provided at the side-view mirrors mainly acquire images on the sides of the vehicle 12100. The imaging unit 12104 provided at the rear bumper or the back door mainly acquires images behind the vehicle 12100. Front view images acquired by the imaging units 12101 and 12105 are mainly used for detection of vehicles ahead, pedestrians, obstacles, traffic lights, traffic signs, lanes, and the like.

FIG. 29 illustrates an example of the imaging ranges of the imaging units 12101 to 12104. An imaging range 12111 indicates the imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, a bird's-eye view image of the vehicle 12100 as viewed from above can be obtained by superimposing pieces of image data captured by the imaging units 12101 to 12104.

At least one of the imaging units 12101 to 12104 may have the function of obtaining distance information. For example, at least one of the imaging units 12101 to 12104 may be a stereo camera including a plurality of imaging elements or may be an imaging element that has pixels for phase difference detection.

For example, the microcomputer 12051 can extract, particularly, a closest three-dimensional object on a path along which the vehicle 12100 is traveling, the object being a three-dimensional object traveling at a predetermined speed (for example, 0 km/h or higher) in the substantially same direction as the vehicle 12100, as a vehicle ahead by acquiring a distance to each three-dimensional object in the imaging ranges 12111 to 12114 and a temporal change of the distance (a relative speed with respect to the vehicle 12100) on the basis of the distance information obtained from the imaging units 12101 to 12104. Furthermore, the microcomputer 12051 can set an inter-vehicle distance to be secured from a vehicle ahead in advance with respect to the vehicle ahead and can perform automated brake control (also including following stop control) or automated acceleration control (also including following start control). In this way, cooperative control can be performed for the purpose of automated driving or the like in which a vehicle autonomously travels without depending on the operations of the driver.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the imaging units 12101 to 12104 and can use the three-dimensional data to perform automated avoidance of obstacles. For example, the microcomputer 12051 identifies surrounding obstacles of the vehicle 12100 as obstacles that are viewable by the driver of the vehicle 12100 and obstacles that are difficult to view. Then, the microcomputer 12051 determines a collision risk indicating the degree of risk of collision with each obstacle, and when the collision risk is equal to or higher than a set value and there is a possibility of collision, an alarm is outputted to the driver through the audio speaker 12061 or the display unit 12062, forced deceleration or avoidance steering is performed through the drive system control unit 12010, and thus it is possible to perform driving support for collision avoidance.

At least one of the imaging units 12101 to 12104 may be an infrared camera that detects infrared rays. For example, the microcomputer 12051 can recognize a pedestrian by determining the presence or absence of a pedestrian in the captured image of the imaging units 12101 to 12104. Such pedestrian recognition is performed by, for example, the step of extracting feature points in the captured images of the imaging units 12101 to 12104 serving as infrared cameras and the step of performing pattern matching on a series of feature points indicating an outline of an object to determine whether or not the object is a pedestrian. When the microcomputer 12051 determines that a pedestrian is present in the captured images of the imaging units 12101 to 12104 and recognizes the pedestrian, the audio/image output unit 12052 controls the display unit 12062 such that a square contour line for emphasis is superimposed and displayed on the recognized pedestrian. In addition, the audio/image output unit 12052 may control the display unit 12062 such that an icon indicating a pedestrian is displayed at a desired position.

An example of the vehicle control system, to which the technique according to the present disclosure (the present technique) is applicable, has been described above. The technique according to the present disclosure may be applied to, for example, the imaging unit 12031 among the configurations described above. Specifically, the solid-state imaging device 111 of the present disclosure can be applied to the imaging unit 12031. By applying the technique according to the present disclosure to the imaging unit 12031, yields can be improved at lower manufacturing cost.

### 8. Example of Application to Endoscopic Surgery System

The present technique can be applied to various products. For example, the technique according to the present disclosure (the present technique) may be applied to an endoscopic surgery system.

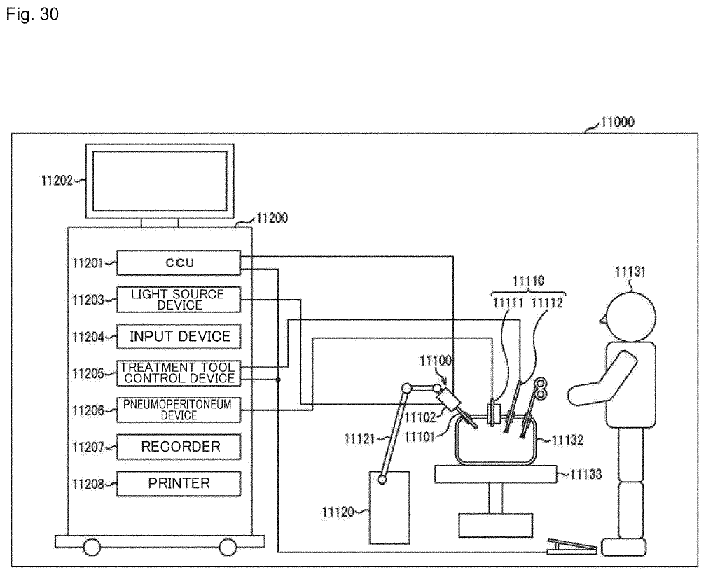

FIG. 30 illustrates an example of a schematic configuration of an endoscope surgery system to which the technique according to the present disclosure (the present technique) is applied.

FIG. 30 illustrates a state in which a surgeon (doctor) 11131 performs surgery on a patient 11132 on a patient bed 11133 using an endoscopic surgery system 11000. As illustrated, the endoscopic surgery system 11000 includes an endoscope 11100, other surgical instruments 11110 such as a pneumoperitoneum tube 11111 and an energy treatment tool 11112, a support arm device 11120 that supports the endoscope 11100, and a cart 11200 equipped with various devices for endoscopic surgery.

The endoscope 11100 includes a lens barrel 11101 on which a region having a predetermined length from the distal end thereof is inserted into the body cavity of the patient 11132, and a camera head 11102 connected to the proximal end of the lens barrel 11101. In the illustrated example, the endoscope 11100 configured as a so-called rigid endoscope having the rigid lens barrel 11101 is illustrated. The endoscope 11100 may be configured as a so-called flexible endoscope having a flexible lens barrel.

The distal end of the lens barrel 11101 is provided with an opening into which an objective lens is fit. A light source device 11203 is connected to the endoscope 11100, light generated by the light source device 11203 is guided to the distal end of the lens barrel 11101 by a light guide extended to the inside of the lens barrel 11101, and the light is radiated toward an observation target in the body cavity of the patient 11132 through the objective lens. The endoscope 11100 may be a direct-viewing endoscope, an oblique-viewing endoscope, or a side-viewing endoscope.

An optical system and an imaging element are provided inside of the camera head 11102, and the reflected light (observation light) from the observation target converges to the imaging element by the optical system. The observation light is photoelectrically converted by the imaging element, and an electrical signal corresponding to the observation light, that is, an image signal corresponding to an observation image is generated. The image signal is transmitted to a camera control unit (CCU) 11201 as RAW data.

The CCU 11201 is configured with a central processing unit (CPU) or a graphics processing unit (GPU) or the like and comprehensively controls the operations of the endoscope 11100 and a display device 11202. In addition, the CCU 11201 receives an image signal from the camera head 11102 and performs various types of image processing for displaying an image based on the image signal, for example, development processing (demosaic processing) on the image signal.

The display device 11202 displays the image based on the image signal subjected to the image processing by the CCU 11201 under the control of the CCU 11201.

The light source device 11203 is configured with, for example, a light source such as an LED (Light Emitting Diode) and supplies irradiation light to the endoscope 11100 when photographing a surgical site or the like.

An input device 11204 is an input interface for the endoscopic surgery system 11000. The user can input various types of information or instructions to the endoscopic surgery system 11000 via the input device 11204. For example, the user inputs an instruction to change imaging conditions (a type of radiation light, a magnification, a focal length, or the like) of the endoscope 11100.

A treatment tool control device 11205 controls driving of the energy treatment tool 11112 for cauterization or incision of a tissue, sealing of blood vessel, or the like. A pneumoperitoneum device 11206 sends gas into the body cavity of the patient 11132 via the pneumoperitoneum tube 11111 in order to inflate the body cavity for the purpose of securing a field of view using the endoscope 11100 and a working space of the surgeon. A recorder 11207 is a device capable of recording various types of information on surgery. A printer 11208 is a device capable of printing various types of information on surgery in various formats such as text, images, and graphs.

The light source device 11203 that supplies, to the endoscope 11100, radiation light for imaging the surgical site can be configured with, for example, an LED, a laser light source, or a white light source as a combination thereof. When a white light source is formed by a combination of RGB laser light sources, an output intensity and an output timing of each color (each wavelength) can be controlled with high accuracy, and thus the light source device 11203 can adjust white balance of the captured image. Furthermore, in this case, laser light from each of the RGB laser light sources is radiated to the observation target in a time division manner, and driving of the imaging element of the camera head 11102 is controlled in synchronization with radiation timing such that images corresponding to respective RGB can be captured in a time division manner. According to this method, a color image can be obtained without providing a color filter in the imaging element.

Furthermore, the driving of the light source device 11203 may be controlled such that the intensity of output light is changed at predetermined time intervals.

The driving of the imaging element of the camera head 11102 is controlled in synchronization with the timing of changing the intensity of the light, and images are acquired in a time division manner and combined, so that an image having a high dynamic range can be generated without causing so-called blackout and whiteout.

In addition, the light source device 11203 may have a configuration in which light in a predetermined wavelength band corresponding to special light observation can be supplied. In the special light observation, for example, by emitting light in a band narrower than that of radiation light (that is, white light) during normal observation using wavelength dependence of light absorption in a body tissue, so-called narrow band light observation (narrow band imaging) is performed in which a predetermined tissue such as a blood vessel in a mucous membrane surface layer is imaged with a high contrast. Alternatively, in the special light observation, fluorescence observation may be performed to obtain an image by fluorescence generated by emitting excitation light. The fluorescence observation can be performed by emitting excitation light to a body tissue and observing fluorescence from the body tissue (autofluorescence observation), or locally injecting a reagent such as indocyanine green (ICG) to a body tissue and emitting excitation light corresponding to a fluorescence wavelength of the reagent to the body tissue to obtain a fluorescence image. The light source device 11203 may be configured such that narrow band light and/or excitation light corresponding to such special light observation can be supplied.

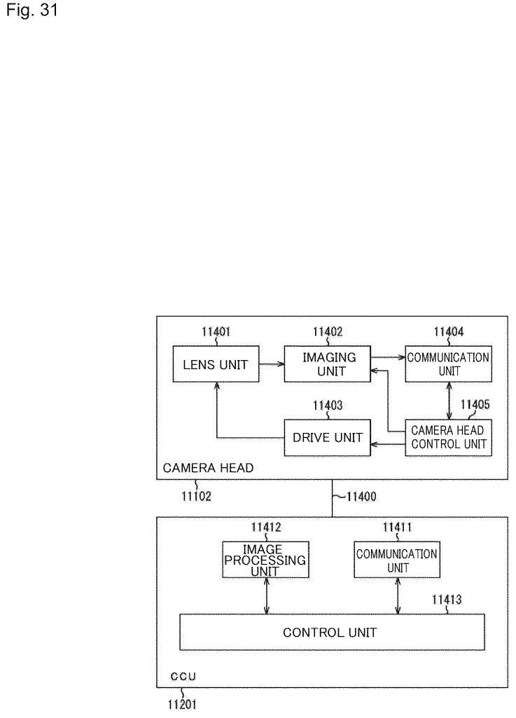

FIG. 31 is a block diagram illustrating an example of the functional configuration of the camera head 11102 and the CCU 11201 that are illustrated in FIG. 30.

The camera head 11102 includes a lens unit 11401, an imaging unit 11402, a drive unit 11403, a communication unit 11404, and a camera head control unit 11405. The CCU 11201 has a communication unit 11411, an image processing unit 11412, and a control unit 11413. The camera head 11102 and the CCU 11201 are communicatively connected to each other via a transmission cable 11400.

The lens unit 11401 is an optical system provided in a connection portion for connection to the lens barrel 11101. Observation light taken from the distal end of the lens barrel 11101 is guided to the camera head 11102 and is incident on the lens unit 11401. The lens unit 11401 is configured as a combination of a plurality of lenses including a zoom lens and a focus lens.

The imaging unit 11402 is configured with an imaging element. The imaging element constituting the imaging unit 11402 may be one element (a so-called single plate type) or a plurality of elements (a so-called multi-plate type). When the imaging unit 11402 is configured as a multi-plate type, for example, image signals corresponding to RGB are generated by the imaging elements, and a color image may be obtained by synthesizing the image signals. Alternatively, the imaging unit 11402 may be configured to include a pair of imaging elements for acquiring image signals for the right eye and the left eye corresponding to three-dimensional (3D) display. The provision of 3D display allows the operator 11131 to determine the depth of biological tissues in the surgical site with higher accuracy. When the imaging unit 11402 is configured as a multi-plate type, a plurality of systems of lens units 11401 may be provided for the imaging elements.

The imaging unit 11402 is not necessarily provided in the camera head 11102. For example, the imaging unit 11402 may be provided directly behind the objective lens inside the lens barrel 11101.

The drive unit 11403 is configured with an actuator, and the zoom lens and the focus lens of the lens unit 11401 are moved by a predetermined distance along an optical axis under the control of the camera head control unit 11405. Accordingly, the magnification and focus of the image captured by the imaging unit 11402 can be properly adjusted.

The communication unit 11404 is configured with a communication device for transmitting and receiving various types of information to and from the CCU 11201. The communication unit 11404 transmits the image signal obtained from the imaging unit 11402 as RAW data to the CCU 11201 via the transmission cable 11400.

The communication unit 11404 receives a control signal for controlling driving of the camera head 11102 from the CCU 11201 and supplies the control signal to the camera head control unit 11405. The control signal includes, for example, information about imaging conditions, for example, information indicating designation of a frame rate of a captured image, information indicating designation of an exposure value at the time of imaging, and/or information indicating designation of a magnification and a focus of the captured image.

The imaging conditions such as the frame rate, the exposure value, the magnification, and the focus may be appropriately specified by the user, or may be automatically set by the control unit 11413 of the CCU 11201 on the basis of the acquired image signal. In the latter case, a so-called auto exposure (AE) function, a so-called auto focus (AF) function, and a so-called auto white balance (AWB) function are provided in the endoscope 11100.

The camera head control unit 11405 controls driving of the camera head 11102 on the basis of a control signal from the CCU 11201 received via the communication unit 11404.

The communication unit 11411 is configured with a communication device that transmits and receives various kinds of information to and from the camera head 11102. The communication unit 11411 receives an image signal transmitted via the transmission cable 11400 from the camera head 11102.

Furthermore, the communication unit 11411 transmits the control signal for controlling the driving of the camera head 11102 to the camera head 11102. The image signal or the control signal can be transmitted through electric communication or optical communication or the like.

The image processing unit 11412 performs various types of image processing on the image signal that is the RAW data transmitted from the camera head 11102.

The control unit 11413 performs various kinds of control on imaging of a surgical site by the endoscope 11100, display of a captured image obtained through imaging of a surgical site or the like. For example, the control unit 11413 generates a control signal for controlling the driving of the camera head 11102.

In addition, the control unit 11413 causes the display device 11202 to display a captured image of a surgical site or the like on the basis of an image signal subjected to the image processing by the image processing unit 11412. At this point, the control unit 11413 may recognize various objects in the captured image using various image recognition techniques. For example, the control unit 11413 can recognize a surgical instrument such as forceps, a specific biological site, bleeding, mist or the like at the time of use of the energy treatment tool 11112 or the like by detecting a shape or a color or the like of an edge of an object included in the captured image. When the display device 11202 is caused to display a captured image, the control unit 11413 may superimpose various kinds of surgery support information on an image of the surgical site for display using a recognition result of the captured image. By displaying the surgery support information in a superimposed manner and presenting the information to the operator 11131, a burden on the operator 11131 can be reduced, and the operator 11131 can reliably conduct the surgery.

The transmission cable 11400 that connects the camera head 11102 and the CCU 11201 is an electrical signal cable compatible with communications of electrical signals, an optical fiber compatible with optical communications, or a composite cable thereof.

Although wire communications are performed using the transmission cable 11400 in the illustrated example, communications between the camera head 11102 and the CCU 11201 may be radio communications.

An example of an endoscopic surgery system to which the technique according to the present disclosure is applicable has been described above. The technique according to the present disclosure can be applied to the endoscope 11100, the camera head 11102 (the imaging unit 11402 thereof), and the like among the configurations described above. Specifically, the solid-state imaging device 111 according to the present technique can be applied to the imaging unit 10402. By applying the technique according to the present disclosure to the endoscope 11100 and the camera head 11102 (the imaging unit 11402 thereof) or the like, yields can be improved at lower manufacturing cost.

The endoscopic surgery system has been described as an example. The technique according to the present disclosure may be applied to other systems, for example, a microscopic surgery system.

In addition, the present technique can also be configured as follows:
(1) A semiconductor device including: a substrate; and
at least one element part provided on the substrate,
wherein
at least a part of the element part is shaped to increase in width toward the substrate, the part including a side opposite to a side near the substrate.
(2) The semiconductor device according to (1) further includes an embedded layer that is embedded around the element part.
(3) The semiconductor device according to (1) or (2), wherein a part of the element part is shaped to increase in width toward the substrate, the part including the side opposite to the side near the substrate.
(4) The semiconductor device according to (1) or (2), wherein element part is entirely shaped to increase in width toward the substrate.
(5) The semiconductor device according to any one of (1) to (4), wherein each of the element part includes a wiring layer disposed on the substrate and a semiconductor layer disposed on the wiring layer, and at least a part of the semiconductor layer is shaped to increase in width toward the substrate, the part including a side opposite to a side near the substrate.
(6) The semiconductor device according to any one of (1) to (5), wherein the semiconductor layer is entirely shaped to increase in width toward the substrate, and at least a part of the wiring layer is shaped to increase in width toward the substrate, the part including a side near the semiconductor layer.
(7) The semiconductor device according to any one of (1) to (6) further includes a protective film covering at least a part of the element part.
(8) The semiconductor device according to any one of (1) to (4), wherein each of the element part includes a wiring layer disposed on the substrate, a semiconductor layer disposed on the wiring layer, and a side wall provided at least near the side of the semiconductor layer, the side wall shaped to increase in width toward the substrate.
(9) The semiconductor device according to (8), wherein the side wall is a part of a protective film covering the semiconductor layer, the wiring layer, and the substrate.
(10) The semiconductor device according to (8) further includes a protective film covering the semiconductor layer, the wiring layer, and the substrate, and the side wall is provided on the sides of the semiconductor layer and the wiring layer with the protective film interposed between the side of the semiconductor layer and the side wall.
(11) The semiconductor device according to any one of (8) to (10), wherein the side wall is made of an inorganic material.
(12) The semiconductor device according to any one of (8) to (11), wherein the side wall is made of a SiN material.
(13) The semiconductor device according to any one of (8) to (12), wherein the widest part of the side wall has a width of 450 nm or more in an in-plane direction.
(14) The semiconductor device according to any one of (1) to (13), wherein the shape is a tapered shape.
(15) The semiconductor device according to any one of (2) to (14), wherein the embedded layer is made of an inorganic material.
(16) The semiconductor device according to any one of (1) to (15), wherein the substrate includes a semiconductor substrate, and a wiring layer disposed on the semiconductor substrate.
(17) The semiconductor device according to any one of (1) to (16), wherein the at least one element part is a plurality of element parts.
(18) The semiconductor device according to any one of (1) to (16), wherein each of the element part is any one of a memory element, a logic element, an analog element, an interface element, and an AI element.
(19) The semiconductor device according to any one of (1) to (17), wherein the substrate includes at least one of a memory element, a logic element, an analog element, an interface element, and an AI element.
(20) The semiconductor device according to any one of (1) to (19), wherein the substrate includes a pixel part having a photoelectric conversion element, and each of the element part processes a signal outputted from the substrate.
(21) A solid-state imaging device including: another substrate including a pixel part having a photoelectric conversion element: and
the semiconductor device according to any one of (1) to (19), the semiconductor device processing a signal outputted from the other substrate.
(22) A method for manufacturing a semiconductor device, the method including: bonding an element chip to a substrate;
forming an inorganic film on the element chip and the substrate; and
forming a side wall near the sides of the element chip by etching the inorganic film, the side wall increasing in width toward the substrate.
(23) The method for manufacturing the semiconductor device according to (22) further including: forming another inorganic film having a smaller thickness than the inorganic film on the element chip and the substrate, after the bonding and before the film-forming.
(24) The method for manufacturing the semiconductor device according to (22) or (23), wherein the forming leaves a part of the inorganic film covering the substrate in the thickness direction and a part of the inorganic film covering a side of the element chip, the side of the element chip being opposite to a side near the substrate.
(25) The method for manufacturing the semiconductor device according to any one of (22) to (24) further including: embedding an inorganic film around the element chip and the side wall, after the forming.
(26) The method for manufacturing a semiconductor device according to (25) further including: polishing the inorganic film to planarize the inorganic film after the embedding.
(27) A method for manufacturing a semiconductor device, the method including: generating an element chip such that at least a part of the element chip is shaped to increase in width from one side, the part of the element chip including the one side in the thickness direction; and
bonding a substrate to a side of the element chip, the side being of the element chip opposite to the one side of the element chip.
(28) The method for manufacturing the semiconductor device according to (27), wherein in the generating, the element chip is generated by dicing a laminate including at least a semiconductor layer and a wiring layer.
(29) The method for manufacturing the semiconductor device according to (27) or (28) further including: embedding an inorganic film around the element chip after the generating.
(30) The method for manufacturing a semiconductor device according to (29) further includes the step of polishing the inorganic film to planarize the inorganic film after the embedding step.

### REFERENCE SIGNS LIST

1-1 to 1-6, 2-1 to 2-4, 3-1 to 3-4 Semiconductor device
10, 11, 12, 13, 20, 21, 22, 23, 30, 31, 32, 33 Element Part
100a, 100a1, 100a2 Semiconductor layer
100b, 100b1, 100b2 Wiring layer
150, 151, 152a, 153a Side wall
152, 153 Protective film
200 Substrate
200a Semiconductor layer
200b Wiring layer
300 Protective film
400 Embedded Layer
400m Inorganic film
501 Solid-state imaging device
W The width of the widest part of the side wall in the in-plane direction.

1. A semiconductor device comprising: a substrate; and
at least one element part provided on the substrate,
wherein
at least a part of the element part is shaped to increase in width toward the substrate, the part including a side opposite to a side near the substrate.

2. The semiconductor device according to claim 1, further comprising an embedded layer that is embedded around the element part.

3. The semiconductor device according to claim 1, wherein a part of the element part is shaped to increase in width toward the substrate, the part including the side opposite to the side near the substrate.

4. The semiconductor device according to claim 1, wherein element part is entirely shaped to increase in width toward the substrate.

5. The semiconductor device according to claim 1, wherein each of the element part comprising:
a wiring layer disposed on the substrate; and
a semiconductor layer disposed on the wiring layer, and
at least a part of the semiconductor layer is shaped to increase in width toward the substrate, the part including a side opposite to a side near the substrate.

6. The semiconductor device according to claim 5, wherein the semiconductor layer is entirely shaped to increase in width toward the substrate, and
at least a part of the wiring layer is shaped to increase in width toward the substrate, the part including a side near the semiconductor layer.

7. The semiconductor device according to claim 1, further comprising a protective film covering at least a part of the element part.

8. The semiconductor device according to claim 1, wherein each of the element part comprising:
a wiring layer disposed on the substrate; and
a semiconductor layer disposed on the wiring layer, and
a side wall provided at least near side of the semiconductor layer,
the side wall shaped to increase in width toward the substrate.

9. The semiconductor device according to claim 8, wherein the side wall is a part of a protective film covering the semiconductor layer, the wiring layer, and the substrate.

10. The semiconductor device according to claim 8, further comprising a protective film covering the semiconductor layer, the wiring layer, and the substrate, and the side wall is provided at least on the sides of the semiconductor layer with the protective film interposed between the side of the semiconductor layer and the side wall.

11. The semiconductor device according to claim 8, wherein the side wall is made of an inorganic material.

12. The semiconductor device according to claim 8, wherein the side wall is made of a SiN material.

13. The semiconductor device according to claim 8, wherein the widest part of the side wall has a width of 450 nm or more in an in-plane direction.

14. The semiconductor device according to claim 1, wherein the shape is a tapered shape.

15. The semiconductor device according to claim 2, wherein the embedded layer is made of an inorganic material.

16. The semiconductor device according to claim 1, wherein the substrate comprising: a semiconductor substrate; and
a wiring layer disposed on the semiconductor substrate.

17. The semiconductor device according to claim 1, wherein the at least one element part is a plurality of element parts.

18. The semiconductor device according to claim 1, wherein each of the element part is any one of a memory element, a logic element, an analog element, an interface element, and an AI element.

19. The semiconductor device according to claim 1, wherein the substrate includes at least one of a memory element, a logic element, an analog element, an interface element, and an AI element.

20. The semiconductor device according to claim 1, wherein the substrate includes a pixel part having a photoelectric conversion element, and each of the element part processes a signal outputted from the substrate.

21. A solid-state imaging device comprising: another substrate including a pixel part having a photoelectric conversion element; and
the semiconductor device according to claim 1, the semiconductor device processing a signal outputted from the other substrate.

22. A method for manufacturing a semiconductor device, the method comprising: bonding an element chip to a substrate;
forming an inorganic film on the element chip and the substrate; and
forming a side wall near sides of the element chip by etching the inorganic film, the side wall increasing in width toward the substrate.

23. The method for manufacturing the semiconductor device according to claim 22, further comprising: forming another inorganic film on the element chip and the substrate, after the bonding and before the film-forming.

24. The method for manufacturing a semiconductor device according to claim 22, wherein the forming leaves a part of the inorganic film covering the substrate in a thickness direction and a part of the inorganic film covering a side of the element chip, the side of the element chip being opposite to a side near the substrate.

25. The method for manufacturing the semiconductor device according to claim 22, further comprising: embedding an embedded material around the element chip and the side wall, after the forming step.

26. The method for manufacturing the semiconductor device according to claim 25, further comprising: polishing the embedded material to planarize the embedded material after the embedding.

27. A method for manufacturing a semiconductor device, the method comprising: generating an element chip such that at least a part of the element chip is shaped to increase in width from one side, the part of the element chip including the one side in a thickness direction; and
bonding a substrate to a side of the element chip, the side of the element chip being opposite to the one side of the element chip.

28. The method for manufacturing the semiconductor device according to claim 27, wherein in the generating, the element chip is generated by dicing a laminate including at least a semiconductor layer and a wiring layer.

29. The method for manufacturing the semiconductor device according to claim 27, further comprising: embedding an embedded material around the element chip, after the generating.

30. The method for manufacturing the semiconductor device according to claim 29, further comprising: polishing the embedded material to planarize the embedded material after the embedding.
